(19) United States
(12) Patent Application Publication
(10) Pub. No.: US 2026/0198119 A1
(43) Pub. Date: Jul. 9, 2026

(54) IMAGE SENSOR WITH META MICROLENS

(71) Applicant: SAMSUNG ELECTRONICS CO., LTD., Suwon-si (KR)

(72) Inventors: Hoonil YANG, Suwon-si (KR); Sanghoon SONG, Suwon-si (KR); Taehyoung KIM, Suwon-si (KR); Taemin KIM, Suwon-si (KR); Somin PARK, Suwon-si (KR)

(73) Assignee: SAMSUNG ELECTRONICS CO., LTD., Suwon-si (KR)

(21) Appl. No.: 19/317,617

(22) Filed: Sep. 3, 2025

(30) Foreign Application Priority Data
Jan. 3, 2025 (KR) 10-2025-0001180

(51) Int. Cl. H10F 39/00

(52) U.S. Cl. CPC H10F 39/8063; H10F 39/805; H10F 39/024

(57) ABSTRACT

Provided is an image sensor and method of manufacturing same, the image sensor including: a substrate including a pixel configured to sense light; at least one meta microlens on the substrate; a reflection prevention layer on the at least one meta microlens; and a nano-post connection layer between the at least one meta microlens and the reflection prevention layer, wherein the at least one meta microlens includes: a dielectric layer; and a nano-post penetrating the dielectric layer and extending upward from the substrate, and wherein the nano-post connection layer is in contact with an upper portion of the nano-post.

### CROSS-REFERENCE TO RELATED APPLICATION

This application is based on and claims priority to Korean Patent Application No. 10-2025-0001180, filed on January 03, 2025, in the Korean Intellectual Property Office, the disclosure of which is incorporated by reference herein in its entirety.

### BACKGROUND

The disclosure relates to an image sensor, and more particularly, to an image sensor including a pixel separation structure separating sensing areas.

Image sensors convert optical images into electrical signals. Generally used image sensors include charge coupled device (CCD)-type image sensors and complementary metal oxide semiconductor (CMOS)-type image sensors (CIS). These image sensors include a plurality of pixels arranged in a two-dimensional matrix form, and each pixel outputs an image signal from light energy. Each of the plurality of pixels accumulates photo charges corresponding to an amount of light incident through a photoelectric conversion device, and outputs a pixel signal based on the accumulated photo charges. Recently, as the degree of integration of image sensors increases, the size of pixels and the size of components of a pixel circuit have decreased.

### SUMMARY

Provided is an image sensor having improved light efficiency.

Further provided is an electronic system including an image sensor having a structure capable of effectively controlling characteristics, such as dark current and white point phenomenon, in each of a plurality of unit pixels, and improving sensitivity.

According to an aspect of the disclosure, an image sensor includes: a substrate including a pixel configured to sense light; at least one meta microlens on the substrate; a reflection prevention layer on the at least one meta microlens; and a nano-post connection layer between the at least one meta microlens and the reflection prevention layer, wherein the at least one meta microlens includes: a dielectric layer; and a nano-post penetrating the dielectric layer and extending upward from the substrate, and wherein the nano-post connection layer is in contact with an upper portion of the nano-post.

According to an aspect of the disclosure, an image sensor includes: a substrate including a photodiode; a meta microlens on the substrate, the meta microlens including a plurality of nano-posts; a nano-post connection layer on the meta microlens; and a reflection prevention layer on the nano-post connection layer, wherein the nano-post connection layer and the plurality of nano-posts are formed by a same process, and wherein the nano-post connection layer extends along an upper surface of the plurality of nano-posts.

According to an aspect of the disclosure, an image sensor includes: a photodiode inside a substrate; a planarization layer on the substrate; at least one meta microlens on the planarization layer; a nano-post connection layer on the meta microlens; and a reflection prevention layer on the nano-post connection layer, wherein the at least one meta microlens includes: a dielectric layer; and a plurality of nano-posts configured to penetrate the dielectric layer and extend upward from the substrate, wherein the nano-post connection layer extends along an upper surface of the plurality of nano-posts and includes a same material as the plurality of nano-posts, and wherein the reflection prevention layer includes a plurality of sub reflection prevention layers each having a different refractive index.

According to an aspect of the disclosure, a method of manufacturing an image sensor includes: forming a planarization layer on a substrate, wherein the substrate includes a plurality of photodiodes; forming an etch stopping layer on the planarization layer; forming a dielectric layer on the etch stopping layer; forming a nitride film coating on the dielectric layer; forming a low temperature oxide layer on the nitride film coating; forming a photoresist on the low temperature oxide layer; performing an exposure process on the photoresist using a mask corresponding to a nano-post pattern; forming the nano-post pattern and a nano-post connection layer by removing the exposed photoresist; forming an upper anti-reflection layer on the nano-post connection layer; and exposing a pad of the substrate.

### BRIEF DESCRIPTION OF DRAWINGS

The above and other aspects and features of certain embodiments of the present disclosure will be more clearly understood from the following detailed description taken in conjunction with the accompanying drawings in which:

FIG. 1 is a schematic, exploded, perspective view of an image sensor according to an embodiment;

FIG. 2 is a block diagram showing some components of an image sensor, according to an embodiment;

FIG. 3 is a schematic, plan view of an image sensor according to an embodiment;

FIG. 4 is a cross-sectional view of the image sensor taken along line I-I' of FIG. 3;

FIG. 5 is a schematic cross-sectional view of an active pixel sensor area of an image sensor, according to an embodiment;

FIGS. 6A, 6B, 6C, 6D, and 6E are enlarged views of area B of FIG. 5 according to one or more embodiments;

FIG. 7 is a schematic cross-sectional view of an image sensor according to an embodiment;

FIGS. 8A, 8B, 8C, and 8D are schematic cross-sectional views of image sensors, according to one or more embodiments;

FIGS. 9A, 9B, 9C, 9D, and 9E are cross-sectional views illustrating a method of manufacturing an image sensor according to a process sequence, according to one or more embodiments;

FIG. 10 is a block diagram of an electronic system according to an embodiment; and

FIG. 11 is a detailed block diagram of a camera module included in the electronic system of FIG. 10.

### DETAILED DESCRIPTION

Hereinafter, one or more embodiments of the disclosure are described in detail with reference to the accompanying drawings. Identical reference numerals are used for the same constituent elements in the drawings, and duplicate descriptions thereof are omitted.

Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

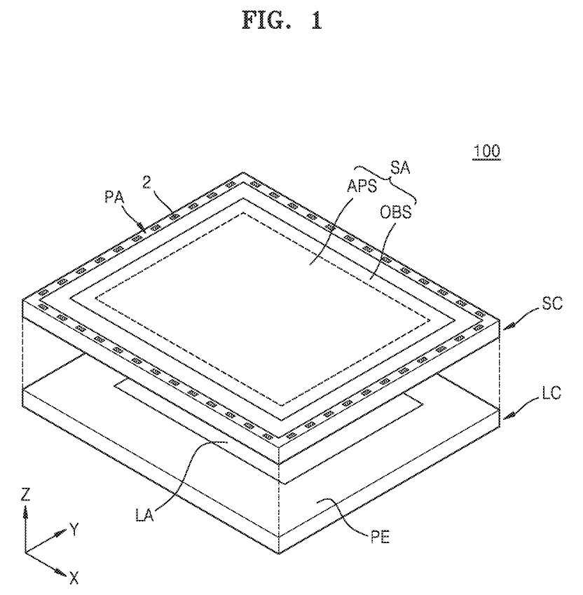

FIG. 1 is a schematic exploded perspective view of an image sensor 100 according to an embodiment.

Referring to FIG. 1, the image sensor 100 may include a first semiconductor chip LC and a second semiconductor chip SC overlapping each other in a vertical direction (Z direction). The first semiconductor chip LC may include a logic chip, and the second semiconductor chip SC may include a sensor chip.

The first semiconductor chip LC may include a logic area LA including logic devices and a periphery circuit area PE including periphery circuits. The logic area LA may surround the periphery circuit area PE.

The second semiconductor chip SC may be stacked on the first semiconductor chip LC to overlap the first semiconductor chip LC in the vertical direction (Z direction). The second semiconductor chip SC may include a sensor array area SA and a pad area PA surrounding the sensor array area SA. In the second semiconductor chip SC, the pad area PA may constitute a periphery circuit area of the second semiconductor chip SC. In another embodiment, the second semiconductor chip SC may include a plurality of through via areas arranged between the sensor array area SA and the pad area PA. The plurality of through via areas and the pad area PA may constitute the periphery circuit area of the second semiconductor chip SC.

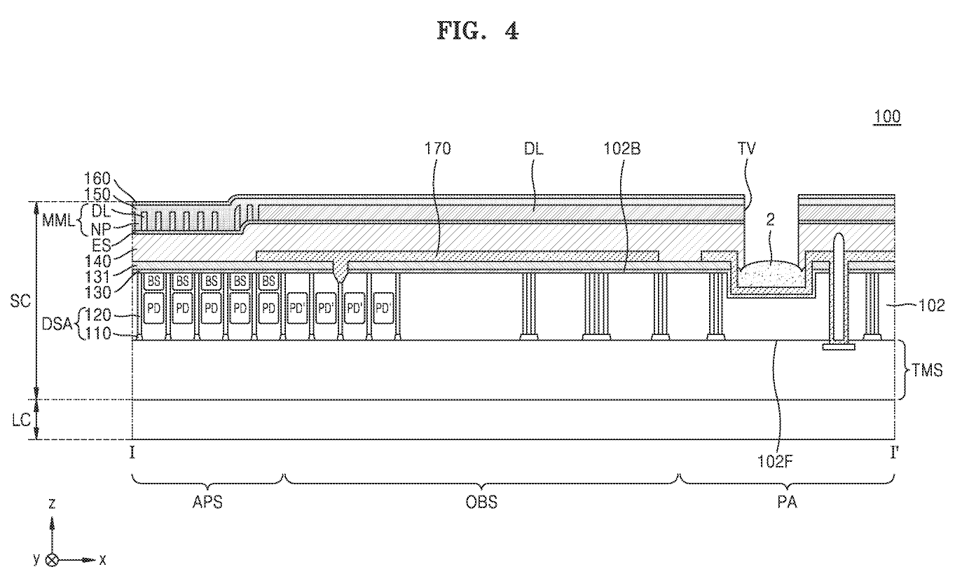

In the second semiconductor chip SC, the sensor array area SA may include an active pixel sensor area APS including an active pixel for generating an active signal corresponding to wavelengths of light from the outside, and an optical black sensor area OBS including an optical black pixel for generating an optical black signal by blocking light from the outside. A dummy pixel sensor (refer to PD' in FIG. 4) may be arranged on an edge portion of the active pixel sensor area APS close to the optical black sensor area OBS. In addition, the dummy pixel sensor (refer to PD' in FIG. 4) may be arranged in the optical black sensor area OBS adjacent to the active pixel sensor area APS.

A plurality of pads 2 may be arranged in the pad area PA of the second semiconductor chip SC. In one or more embodiments, the plurality of pads 2 may exchange electrical signals with an external device. In other embodiments, the plurality of pads 2 may transmit a driving power, such as an externally supplied power voltage and a ground voltage, to circuits inside the second semiconductor chip SC.

The plurality of through vias may be disposed in a plurality of through via regions included in the second semiconductor chip SC. Some of the plurality of through vias may be connected to unit pixels in the sensor array area SA via wirings included in the second semiconductor chip SC. Some others of the plurality of through vias may interconnect wirings included in the first semiconductor chip LC to the wirings included in the second semiconductor chip SC. Some others of the plurality of through vias may interconnect wirings included in the first semiconductor chip LC to logic devices of the logic area LA included in the second semiconductor chip SC.

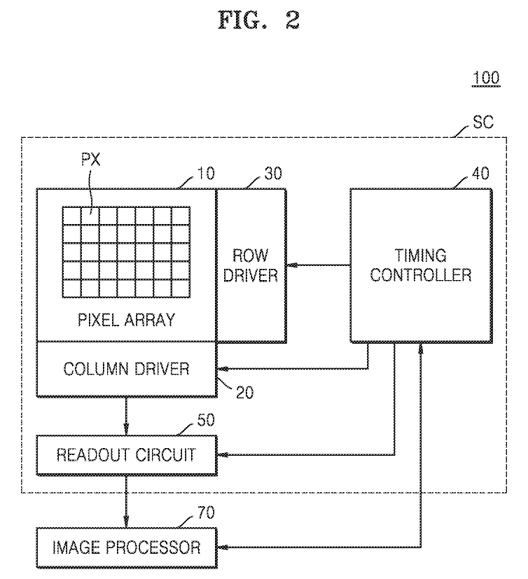

FIG. 2 is a block diagram showing some components of the image sensor 100 illustrated in FIG. 1.

Referring to FIGS. 1 and 2, the image sensor 100 may include a pixel array 10 arranged in the sensor array area SA, and circuits for controlling the pixel array 10. In one or more embodiments, circuits for controlling the pixel array 10 may include a column driver 20, a row driver 30, a timing controller 40, and a readout circuit 50.

The image sensor 100 may operate according to a control command received from an image processor 70, and may convert light transmitted by an external object into an electrical signal and output the electrical signal to the image processor 70. The image sensor 100 may include a complementary metal-oxide semiconductor (CMOS) image sensor.

The pixel array 10 may include a plurality of unit pixels PX having a two-dimensional array structure arranged in a matrix form along a plurality of row lines and a plurality of column lines. The term unit pixel used in the disclosure may be simply referred to as a pixel.

Each of the plurality of unit pixels PX may include a photodiode. The photodiode may generate electric charges by receiving light transmitted by the object. The image sensor 100 may perform an auto-focus function by using a phase difference between pixel signals generated by a plurality of photodiodes respectively included in the plurality of unit pixels PX. Each of the plurality of unit pixels PX may include a pixel circuit for generating a pixel signal from a charge generated by a photodiode.

In one or more embodiments, the image sensor 100 may include an image sensor capable of performing a global shutter operation. For example, when the image sensor 100 operates, all unit pixels PX included in the pixel array 10 may be simultaneously exposed to light signals provided from the outside, and accordingly, charges may be simultaneously stored in each of the unit pixels PX. In one or more embodiments, pixel signals generated by electric charges stored in each of the plurality of unit pixels PX may be sequentially output for each row.

The column driver 20 may include a correlated double sampler (CDS), an analog-to-digital converter (ADC), etc. The CDS may be connected to the unit pixel PX included in the row selected by a row selection signal supplied by the row driver 30 via column lines, and may detect a reset voltage and a pixel voltage by performing a correlated double sampling process. The ADC may convert the reset voltage and the pixel voltage detected by the correlated double sampler into digital signals and transmit the digital signals to the readout circuit 50.

The readout circuit 50 may include a latch circuit, a buffer circuit, an amplification circuit, or the like, capable of temporarily storing the digital signal, and may generate image data by temporarily storing or amplifying the digital signal received from the column driver 20. The operation timing of the column driver 20, the row driver 30, and the readout circuit 50 may be determined by the timing controller 40, and the timing controller 40 may operate according to the control command transmitted by the image processor 70.

The image processor 70 may process image data output by the readout circuit 50 into a signal, and output the signal onto a display device or store the signal in a storage device such as a memory. When the image sensor 100 is mounted on the autonomous vehicle, the image processor 70 may process image data into a signal and transmit the signal to a main controller or the like that controls the autonomous vehicle.

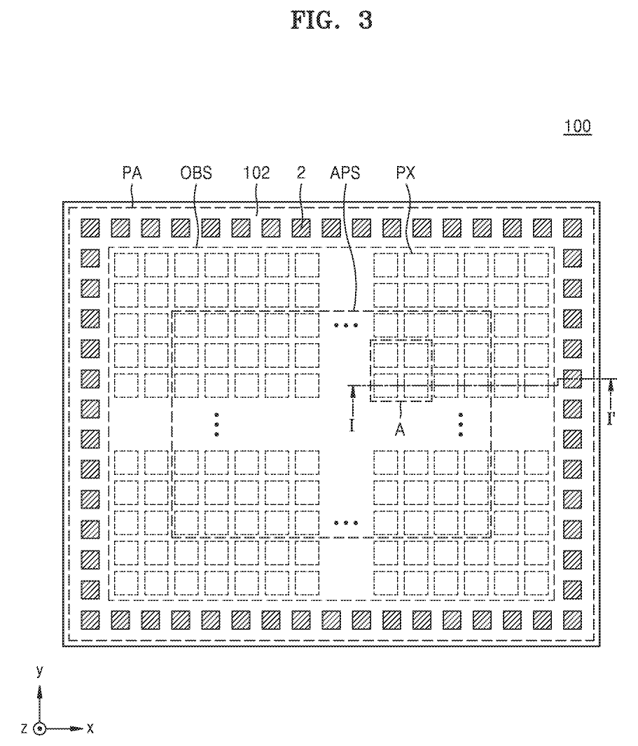

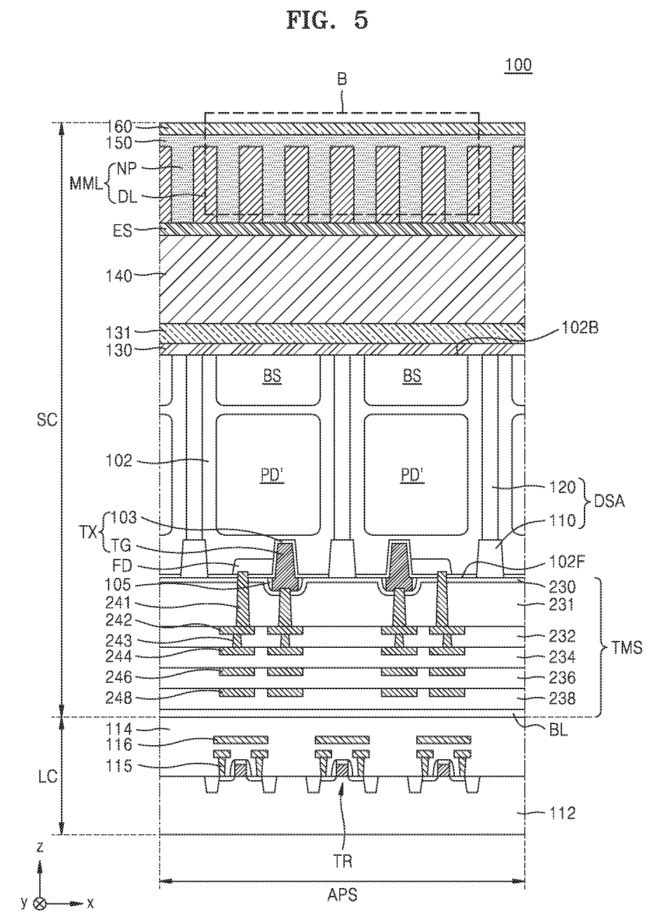

FIG. 3 is a plan view of the image sensor 100 according to an embodiment, FIG. 4 is a cross-sectional view of the image sensor 100 taken along line I-I' in FIG. 3, and FIG. 5 is a schematic cross-sectional view of an active pixel sensor area of the image sensor 100, according to an embodiment.

Referring to FIGS. 3 through 5, in the image sensor 100, the first semiconductor chip LC and the second semiconductor chip SC may be bonded to each other by using a bonding layer BL. The plurality of unit pixels PX for generating an active signal corresponding to wavelengths of light from the outside may be arranged in the active pixel sensor area APS of the second semiconductor chip SC.

The image sensor 100 may include a substrate 102. The substrate 102 may include a semiconductor layer. In one or more embodiments, the substrate 102 may include a semiconductor layer doped with P-type impurities. For example, the substrate 102 may include a semiconductor layer including Si, Ge, SiGe, a Group II-VI compound semiconductor, a Group II-V compound semiconductor, or a combination thereof. In one or more embodiments, the substrate 102 may include a P-type epitaxial semiconductor layer epitaxially grown from a P-type bulk silicon substrate. The substrate 102 may have a frontside surface 102F and a backside surface 102B, which are on opposite sides of the substrate 102.

Each of the plurality of unit pixels PX may include a photodiode PD, a scattering layer BS, a floating diffusion region FD, and a transfer transistor TX. The photodiode PD and the floating diffusion region FD may be arranged in the substrate 102. The photodiode PD may generate charge in proportion to the amount of light incident from the outside. The charge generated in this manner may be accumulated in the photodiode PD, and the charges accumulated in the photodiode PD may be transmitted to the floating diffusion region FD. The charge transmitted to the floating diffusion region FD may be applied to a source follower gate included in the unit pixel PX. One end of the transfer transistor TX may be connected to the photodiode PD, and the other end of the transfer transistor TX may be connected to the floating diffusion region FD. The transfer transistor TX may transmit the charge generated by the photodiode PD to the floating diffusion region FD.

As illustrated in FIG. 5, the transfer transistor TX may include a transfer gate TG and a gate insulating layer 103. Sidewalls of the transfer gate TG may be covered by an insulating spacer 105. The transfer gate TG may include a portion buried in the substrate 102. The gate insulating layer 103 may be arranged between the transfer gate TG and the substrate 102.

The scattering layer BS may be formed in a trench formed to face the frontside surface 102F from the backside surface 102B of the substrate 102 to improve the sensitivity of the image sensor 100.

The scattering layer BS may include a matrix including a transparent resin having a high transmittance in an infrared band and a scattering material arranged in the matrix. The transparent resin may include a material having a high transmittance in an infrared band, and may include, for example, polysiloxane resin, silicone resin, etc.

The scattering material may enhance light sensitivity of the photodiode PD by scattering incident light in the infrared band. The scattering material may include particles having a refractive index different from that of the transparent resin and exhibiting good scattering characteristics in the infrared band. For example, the scattering material may include inorganic particles, such as HfO, TiO₂, Al₂O₃, and ZrO₂. In particular, HfO may have good scattering characteristics and high thermal stability in the infrared band.

The thickness of the scattering layer BS may be selected, for example, in a range of about 0.5 μm to about 5 μm. When the thickness of the scattering layer BS is excessively thin, it may be difficult to obtain a sufficient scattering effect, and when the scattering layer BS is excessively thick, the transmittance of incident light may be reduced.

The particle size of the scattering material may be selected in a range of about 100 nm to about 1000 nm. Scattering materials in such a size range may provide effective scattering characteristics in the infrared band. The content of the scattering material may be selected in a range of about 5 wt% to about 40 wt% with respect to the transparent resin.

The trench of the scattering layer BS may be formed to have a size corresponding to the light-receiving area of the photodiode PD. The sidewalls of the trench may be formed at an angle of about 75° to about 90° with respect to the vertical direction (Z direction) to effectively induce incident light to the photodiode PD.

The scattering layer BS may need to be uniformly formed without a void or a gap in the trench. To this end, the scattering layer BS may be formed by filling a mixture of a transparent resin and a scattering material in the trench and then performing a heat treatment process. The heat treatment temperature and time may be appropriately selected in consideration of curing characteristics of the transparent resin.

A pixel separation structure DSA may include a local device separation layer 110 and a main device separation layer 120. The main device separation layer 120 may have a structure penetrating from the frontside surface 102F to the backside surface 102B of the substrate 102 in the vertical direction (Z direction) to limit the plurality of unit pixels PX. The local device separation layer 110 may penetrate only a portion of the substrate 102 from the frontside surface 102F of the substrate 102 in the vertical direction (Z direction), and may cover a portion of sidewalls of the main device separation layer 120 adjacent to the frontside surface 102F. In the disclosure, the vertical direction (Z direction) may be a direction perpendicular to the backside surface 102B of the substrate 102. In one or more embodiments, the local device separation layer 110 may include a silicon oxide layer.

As illustrated in FIG. 5, an etching stop layer 230 covering the transfer gate TG may be arranged on the frontside surface 102F of the substrate 102. The etching stop layer 230 may conformally cover a transfer gate TG, the insulating spacer 105, the floating diffusion region FD, and the pixel separation structure DSA. The etching stop layer 230 may include silicon nitride, silicon oxynitride, or a combination thereof, but the disclosure is not limited thereto.

A wiring structure TMS may be arranged on the frontside surface 102F of the substrate 102. In other words, the wiring structure TMS may be arranged on the etching stop layer 230 on an upper portion of the frontside surface 102F.

The wiring structure TMS may include a plurality of interlayer insulating layers 231, 232, 234, 236, and 238 covering a plurality of transfer transistors TX, a plurality of via contacts 241 and 243 and a plurality of wiring layers 242, 244, 246, and 248, which are covered by the plurality of interlayer insulating layers 231, 232, 234, 236, and 238, and a bonding layer BL. Some of the plurality of via contacts 241 and 243 may electrically connect the floating diffusion region FD to the plurality of wiring layers 242, 244, 246, and 248.

The number and arrangement of stacks of each of the plurality of interlayer insulating layers 231, 232, 234, 236, and 238 and the plurality of wiring layers 242, 244, 246, and 248 are not limited to those illustrated in FIG. 5, and various changes and modifications may be made as necessary.

The plurality of wiring layers 242, 244, 246, and 248 may include conductive lines connected to a plurality of transistors electrically connected to the photodiode PD. The electrical signals converted by the photodiode PD may be signal-processed by using the plurality of wiring layers 242, 244, 246, and 248.

In one or more embodiments, each of the plurality of interlayer insulating layers 231, 232, 234, 236, and 238 may include a silicon oxide layer, a silicon nitride layer, a silicon oxynitride layer, a low dielectric layer having a lower dielectric constant than a silicon oxide layer, or a combination thereof, but the disclosure is not limited thereto.

In one or more embodiments, each of the plurality of via contacts 241 and 243 and the plurality of wiring layers 242, 244, 246, and 248 may include tungsten (W), copper (Cu), aluminum (Al), gold (Au), silver (Ag), or a combination thereof, but the disclosure is not limited thereto.

As illustrated in FIG. 5, the first semiconductor chip LC may include a logic substrate 112 and a plurality of transistors TR arranged on the logic substrate 112. The plurality of transistors TR may constitute a logic circuit. In one or more embodiments, the plurality of transistors TR may constitute a circuit for controlling transistors included in the second semiconductor chip SC.

An interlayer insulating layer 114 covering the plurality of transistors TR, a plurality of via contacts 115 covered by the interlayer insulating layer 114, and a plurality of wiring layers 116 may be arranged on the logic substrate 112. The plurality of transistors TR may be electrically and respectively connected to the plurality of wiring layers 116 via the plurality of via contacts 115. The interlayer insulating layer 114 may include a silicon oxide layer, a silicon nitride layer, a silicon oxynitride layer, a low dielectric layer having a lower dielectric constant than a silicon oxide layer, or a combination thereof, but the disclosure is not limited thereto. Each of the plurality of via contacts 115 and the plurality of wiring layers 116 may include W, Cu, Al, Au, Ag, or a combination thereof, but the disclosure is not limited thereto.

Referring to FIGS. 4 and 5, the image sensor 100 may include a backside insulating layer 130, a lower anti-reflection layer 131, a light blocking layer 170, a planarization layer 140, an etching stopper ES, a meta microlens MML, a nano-post connection layer 150, and an upper anti-reflection layer 160, which cover the backside surface 102B of the substrate 102.

The backside insulating layer 130 may be arranged on the backside surface 102B of the substrate 102. The backside insulating layer 130 may be formed in the active pixel sensor area APS, the optical black sensor area OBS, and the pad area PA.

The backside insulating layer 130 may include silicon oxide, silicon nitride, or a combination thereof. In particular, the backside insulating layer 130 may include an insulating material having excellent light transmittance to improve light sensitivity in the active pixel sensor area APS.

The thickness of the backside insulating layer 130 may be optimized considering both optical characteristics and insulation characteristics. In an embodiment, the thickness of the backside insulating layer 130 may be in a range of, for example, about 1000 Å to about 5000 Å. This thickness range may optimize light transmittance while providing sufficient insulation characteristics.

The backside insulating layer 130 may be formed by using a chemical vapor deposition (CVD) process or an atomic layer deposition (ALD) process. In particular, when the ALD process is used, good step coatability and uniform thickness distribution may be obtained.

The backside insulating layer 130 may be formed, for example, in a multilayer structure. For example, the backside insulating layer 130 may have a structure in which a silicon oxide layer and a silicon nitride layer are alternately stacked. This multilayer structure may further improve insulation characteristics and interfacial characteristics.

The lower anti-reflection layer 131 may be arranged on the backside insulating layer 130. In FIG. 5, the lower anti-reflection layer 131 is illustrated as a single layer, but the disclosure is not limited thereto, and the lower anti-reflection layer 131 may include a plurality of layers. The lower anti-reflection layer 131 may improve light utilization efficiency of the pixel array by reducing light reflected by the backside surface 102B of the substrate 102, among incident light. The lower anti-reflection layer 131 may be formed to have a thickness of, for example, about 80 nm to about 120 nm.

The light blocking layer 170 may be arranged between the lower anti-reflection layer 131 and the planarization layer 140, and may be arranged in the optical black sensor area OBS and the pad area PA outside the active pixel sensor area APS. The light blocking layer 170 may be formed to cover the entire optical black sensor area OBS and pad area PA, starting from an outer boundary of the active pixel sensor area APS. This structure may effectively block unwanted light leakage into the active pixel sensor area APS.

The light blocking layer 170 may include, for example, tungsten (W). Tungsten may have good light blocking characteristics in the visible light region, and good compatibility with semiconductor processes. In addition, tungsten may have high thermal stability and good mechanical strength, and thus may maintain stable characteristics despite heat treatment or mechanical stress in subsequent processes.

The thickness of the light blocking layer 170 may be optimized considering a light blocking effect and processability. When the thickness of the light blocking layer 170 is excessively thin, a sufficient light blocking effect may not be obtained, and when excessively thick, the flatness of the subsequent layers may be affected. In an embodiment, the thickness of the light blocking layer 170 may be in a range of, for example, about 1000 Å to about 3000 Å.

The light blocking layer 170 may be formed by using a selective deposition process. For example, the light blocking layer 170 including tungsten may be formed by using a CVD process or PVD process. After deposition, the surface of the light blocking layer 170 may be planarized by using a chemical mechanical polishing (CMP) process.

The light blocking layer 170 may be formed to have good adhesion force to, for example, the planarization layer 140 formed thereon. To this end, a surface treatment process on the light blocking layer 170 may be additionally performed.

A patterning operation on the light blocking layer 170 may be performed by using a photolithography process. In this case, the pattern of the light blocking layer 170 may be formed to correspond to the outer boundary of the active pixel sensor area APS to maximize the light blocking effect.

The planarization layer 140 may be arranged on the lower anti-reflection layer 131. In other words, the planarization layer 140 may be arranged between the lower anti-reflection layer 131 and the meta microlens MML. The planarization layer 140 may maintain a uniform distance between the substrate 102 and the meta microlens MML.

The planarization layer 140 may include a transparent material with respect to visible light, for example, tetraethyl orthosilicate (TEOS), SiO₂, siloxane-based spin-on-glass (SOG). The planarization layer 140 may include a dielectric material having a lower absorption rate in the infrared band while having a lower refractive index than a nano-post NP of the meta microlens MML.

The thickness of the planarization layer 140 may be determined based on a focal length of light concentrated by the meta microlens MML. For example, the thickness of the planarization layer 140 may be in a range of, for example, about 1/2 to about 1.5 times a focal length of a reference wavelength (λ0).

The meta microlens MML may be arranged on the planarization layer 140. In other words, the meta microlens MML may be supported by the planarization layer 140, and may include the nano-posts NP having a high refractive index and being configured to change phases of incident light, and dielectric layers DL arranged between the nano-posts NP and including a dielectric material having a lower refractive index than the nano-posts NP.

The nano-posts NP may include, for example, TiO₂. The dielectric material of the dielectric layer DL may include, for example, air, SiO₂, or TEOS. The diameters of the nano-posts NP may be different from each other. The distances of the nano-posts NP apart from each other in the horizontal direction may be different from each other.

The meta microlens MML may not only condense incident light regardless of wavelength, but may condense incident light by changing the phase for each wavelength.

The etching stopper ES may be arranged between the meta microlens MML and the planarization layer 140. The etching stopper ES may be arranged between the planarization layer 140 and the corresponding nano-posts NP to protect the planarization layer 140 from being damaged in the process of forming the nano-posts NP.

The etching stopper ES has a relatively large etch selectivity with respect to the planarization layer 140 and may include a transparent dielectric material. For example, the etching stopper ES may include at least one material of aluminum oxide (AlO), hafnium oxide (HfO), and silicon nitride (SiN).

The etching stopper ES may have a thickness capable of performing a function of protecting a lower layer, that is, the planarization layer 140, without impairing the optical characteristics of the meta microlens MML. The thickness of the etching stopper ES may be, for example, about 3 nm to about 50 nm, or about 5 nm to about 15 nm.

To reduce the increase in reflectance due to the etching stopper ES, the etching stopper ES may be arranged such that, for example, the etching stopper ES does not completely cover the entire surface of the planarization layer 140. In other words, the etching stopper ES may be arranged to cover only a portion of an upper surface of the planarization layer 140. For example, each etching stopper ES may be arranged only under the nano-post NP corresponding thereto, and because the etch stoppers ES are separated from each other, the upper surface of the planarization layer 140 may be in direct contact with a lower surface of the dielectric layer DL in the area between the etching stoppers ES. Because the refractive index of the planarization layer 140 is substantially the same as the refractive index of the dielectric layer DL, little reflection may occur at the interface between the planarization layer 140 and the dielectric layer DL. Accordingly, by reducing the total area of the etching stoppers ES, the increase in reflectance at the interface between the planarization layer 140 and the etching stopper ES may be reduced.

The nano-post connection layer 150 may be formed on the meta microlens MML, and may be formed to be in contact with one end of the nano-posts NP.

The nano-posts NP may have a pillar shape extending in the vertical direction (Z direction), and an upper end of the nano-posts NP may be in contact with and connected to the nano-post connection layer 150. An upper end surface of the nano-posts NP may be at one end facing the upper anti-reflection layer 160, and this upper end surface may be in surface-contact with and connected to a lower surface of the nano-post connection layer 150.

The method of forming the nano-post connection layer 150 may be implemented in two ways. A first method of forming the nano-post connection layer 150 may include forming the nano-post connection layer 150 continuously by using the same material in the same process as the nano-posts NP. In this case, by continuing the deposition process of forming the nano-posts NP to form the nano-post connection layer 150, a separate CMP process may be unnecessary. When the same material is used, TiO₂, SiN, SiC, or a Group III/V compound semiconductor, such as GaAs, InP, and GaN may be applied.

A second method of forming the nano-post connection layer 150 may include forming the nano-post connection layer 150 by using a separate process after the process of forming the nano-posts NP. In this case, the nano-post connection layer 150 may be formed by using a different material from the nano-posts NP. For example, even when the nano-posts NP are formed of TiO₂, the nano-post connection layer 150 may be formed of a different material, for example, SiN, SiC, etc. These methods may be advantageous in independently optimizing characteristics of the nano-post connection layer 150.

The nano-post connection layer 150 may be continuously formed over an area including all of the active pixel sensor area APS, the optical black sensor area OBS, and the pad area PA of the image sensor 100.

The thickness of the nano-post connection layer 150 may be designed in consideration of a relation with a height of the nano-posts NP. The thickness of the nano-post connection layer 150 may be determined to maximize structural stability and optical performance.

The nano-post connection layer 150 may be formed in consideration of interfacial characteristics with respect to the upper anti-reflection layer 160 formed thereon. Because the surface characteristics of the nano-post connection layer 150 may affect adhesion and optical characteristics with respect to the upper anti-reflection layer 160, the surface roughness and flatness of the nano-post connection layer 150 may be controlled.

The upper anti-reflection layer 160 may be arranged on the light incident surface of the meta microlens MML. In FIG. 5, the upper anti-reflection layer 160 is illustrated as a single layer, but the disclosure is not limited thereto, and the upper anti-reflection layer 160 may include two or more multiple layers.

In an embodiment where the upper anti-reflection layer 160 includes a plurality of layers, the plurality of layers may be stacked to overlap each other in the vertical direction (Z direction).

The refractive index of the upper anti-reflection layer 160 may be less than the refractive index of the meta microlens MML, and may be greater than the refractive index of air. In an embodiment, when the refractive index of the meta microlens MML is about 1.69, the refractive index of the upper anti-reflection layer 160 may be greater than about 1 and less than about 1.69.

In an embodiment where the upper anti-reflection layer 160 includes a plurality of layers, the refractive index of the upper anti-reflection layer 160 may increase toward the meta microlens MML. For example, in the upper anti-reflection layer 160, when a third sub reflection layer, a second sub reflection layer, and a first sub reflection layer are stacked over the meta microlens MML, the refractive index of the second sub reflection layer may be less than the refractive index of the third sub reflection layer, and may be greater than the refractive index of the first sub reflection layer. For example, the refractive index of each of a plurality of upper anti-reflection layers 160 may linearly increase by about 0.2 for every about 100 nm of thickness in the vertical direction (Z direction) of each of the plurality of upper anti-reflection layers 160. In other words, as each of the plurality of upper anti-reflection layers 160 is closer toward the meta microlens MML, the refractive index of each of the plurality of upper anti-reflection layers 160 may increase. When the refractive index of the first sub reflection layer is about 1.22 and the thickness thereof is about 1000 Å, the refractive index of the second sub reflection layer may be about 1.35. In an embodiment, when the refractive index of the second sub reflection layer is about 1.35, and the thickness thereof is about 1000 Å, the refractive index of the third sub reflection layer may be about 1.46, and the thickness thereof may be about 1000 Å.

Because the refractive index of the upper anti-reflection layer 160 increases toward the meta microlens MML, when the incident light incident on the meta microlens MML is reflected by the incident light surface of the meta microlens MML, a path of light may be formed from a section having a greater refractive index to a section having a less refractive index. Accordingly, because the reflected light goes from the upper anti-reflection layer with a high refractive index to the upper anti-reflection layer with a less refractive index, total reflection or refraction may occur at the interface, less reflection may occur, and the intensity of the reflected light may be reduced.

For example, when the incident light proceeds after being reflected from the third sub reflection layer to the second sub reflection layer, and when the incident angle is formed at a greater angle than a threshold angle determined by respective refractive indices of the third sub reflection layer and the second sub reflection layer, the incident light may be totally reflected at the boundary surface of the third sub reflection layer and the second sub reflection layer. The path of the incident light described above may be the same even at the boundary surface between the first sub reflection layer and the second sub reflection layer, and may be applied equally at the boundary surface between the meta microlens MML and the third sub reflection layer.

Thicknesses of the first sub reflection layer, the second sub reflection layer, and the third sub reflection layer may be different from each other. The thickness of each of the first sub reflection layer, the second sub reflection layer, and the third sub reflection layer may be in a range of about 100 Å to about 2000 Å.

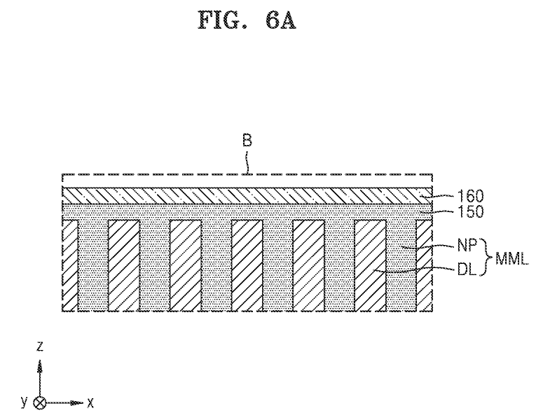

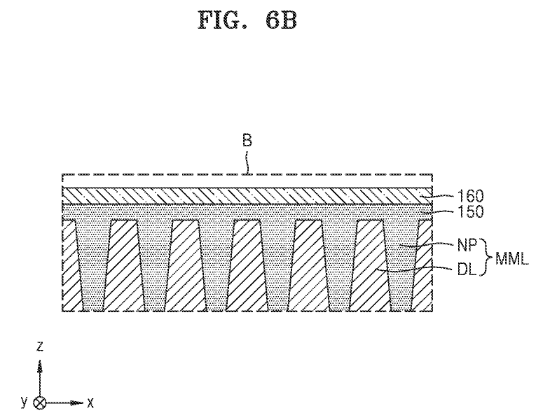

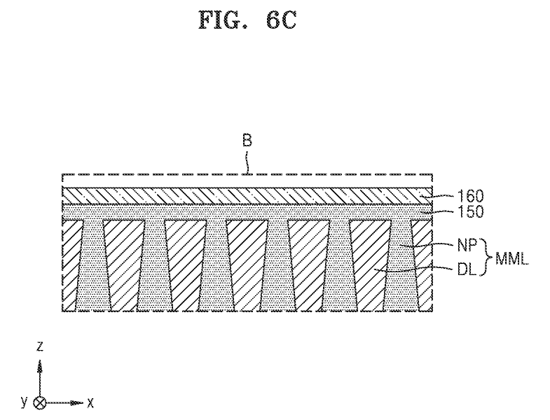

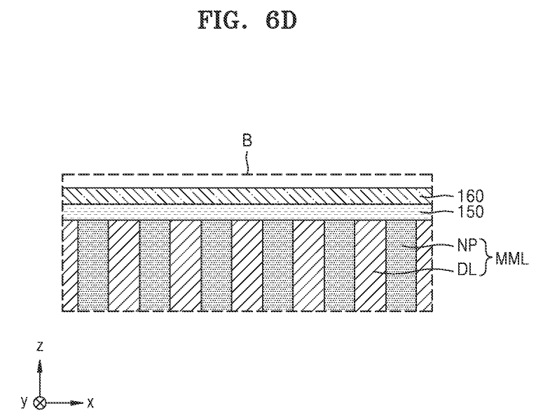

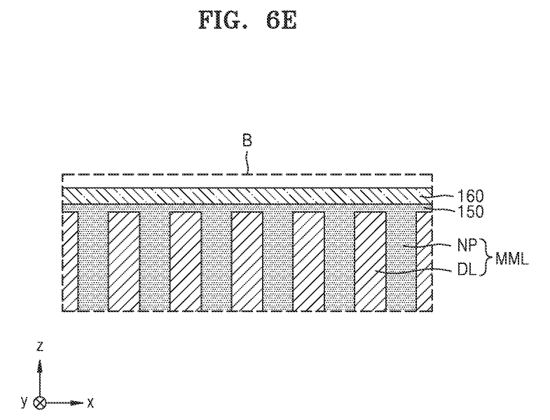

FIGS. 6A through 6E are enlarged views of area B in FIG. 5 according to one or more embodiments.

FIG. 6A is a cross-sectional view illustrating a meta microlens area of the image sensor 100 according to an embodiment. FIG. 6A is an enlarged view of the area B in FIG. 5, and illustrates in detail the structure of the meta microlens MML, the nano-post connection layer 150, and the upper anti-reflection layer 160.

Referring to FIG. 6A, the meta microlens MML may be arranged on the planarization layer 140, and may include a plurality of nano-posts NP and a plurality of dielectric layers DL. The nano-posts NP may have a right-angled column structure extending in the vertical direction (Z direction). The right-angled nano-posts NP may include sidewalls formed in parallel with the vertical direction (Z direction).

The nano-posts NP may extend upward from the planarization layer 140, and an upper end the nano-post NP may be in contact with and connected to the nano-post connection layer 150. The nano-post connection layer 150 may include the same material as the nano-posts NP, and may be continuously formed in the same process. By using this forming method, good connection characteristics may be secured at the interface between the nano-post NP and the nano-post connection layer 150.

The upper anti-reflection layer 160 may be formed on the nano-post connection layer 150. The upper anti-reflection layer 160 may effectively reduce reflection of the incident light.

FIG. 6B is a cross-sectional view of a meta microlens area of the image sensor 100 according to another embodiment. Like FIG. 6A, FIG. 6B may be an enlarged view of the area B in FIG. 5, but may show a difference in the shape of the nano-posts NP.

In FIG. 6B, the nano-posts NP may have a reverse tapered shape. The nano-posts NP may have a shape in which a cross-sectional area thereof gradually increases from the planarization layer 140 toward the upper portion of the nano-posts NP. This shape may have a characteristic structure contrasted with the right-angled nano-post NP illustrated in FIG. 6A.

Sidewalls of the nano-post NP having the reverse tapered shape may be inclined at a certain angle with respect to the vertical direction (Z direction). This inclination angle may be an important design variable to determine optical characteristics of a nano-post. Due to the reverse taper structure, the cross-sectional area of the upper end portion of the nano-post NP may be greater than the cross-sectional area of the lower end portion thereof.

As in the case of FIG. 6A, the nano-post connection layer 150 may include the same material as the nano-post NP, and may be continuously formed in the same process. However, an area of a boundary surface in contact with the reverse taper nano-post NP may be greater than that in FIG. 6A.

The structure of the dielectric layer DL between the nano-posts NP may also vary depending on the reverse tapered shape of the nano-post NP. The dielectric layer DL may be formed in a shape in which a space that decreases toward the upper portion of the space is filled.

A nano-post structure of a reverse tapered shape may improve condensing characteristics of incident light, and structural stability may be improved by increasing a contact area with the nano-post connection layer 150.

FIG. 6C is a cross-sectional view of a meta microlens area of the image sensor 100, according to another embodiment. FIG. 6C may be an enlarged view of area B inf FIG. 5, but the shape of the nano-post NP may be different from that of FIG. 6A.

In FIG. 6C, the nano-posts NP may have a tapered shape. The nano-posts NP may have a shape in which a cross-sectional area thereof gradually decreases from the planarization layer 140 toward the upper portion thereof. The shape may have a characteristic structure contrasted with the nano-posts having a right angle shape illustrated in FIG. 6A or the reverse tapered shape illustrated in FIG. 6B.

The sidewalls of the nano-posts NP having the tapered shape may be inclined at a certain angle with respect to the vertical direction (Z direction). The cross-sectional area of the upper end portion of the nano-post NP may be smaller than the cross-sectional area of the lower end portion, and this structure may affect the path of the incident light.

As in the case of FIG. 6A, the nano-post connection layer 150 may include the same material as the nano-post NP, and may be continuously formed in the same process. However, an area of a boundary surface in contact with the nano-posts NP having the tapered shape may be less than that in FIG. 6A.

The structure of the dielectric layer DL between the nano-posts NP may also vary depending on the tapered shape of the nano-post NP. The dielectric layer DL may be formed in a shape in which a space that increases toward the upper portion of the space is filled. This structure may affect the optical characteristics of the dielectric layer DL.

The nano-post structure having a tapered shape may improve selective transmittance characteristics with respect to light in a particular wavelength band. In addition, this structure may improve the filling characteristics of the dielectric layer DL during the manufacturing process, and accordingly, may affect the overall optical performance of the meta microlens MML.

FIG. 6D is a cross-sectional view of a meta microlens area of the image sensor 100, according to another embodiment. Like FIG. 6A, FIG. 6D may be an enlarged view of the area B in FIG. 5, but may show a difference in the method of forming the nano-post connection layer 150.

In FIG. 6D, the nano-posts NP may have a right-angled column structure extending in the vertical direction (Z direction) in the same manner as illustrated in FIG. 6A. However, a method of forming the nano-post connection layer 150 may be different from that in FIG. 6A. The nano-post connection layer 150 may be formed by using a separate process after the forming of the nano-posts NP is completed. In other words, after the forming of the nano-post NP is completed, the material of the nano-posts NP remaining on the upper surface of the dielectric layer DL may be removed by using a CMP process. Thereafter, the nano-post connection layer 150 may be formed by using a separate process.

Due to this separate process forming method, the nano-post connection layer 150 may include a material different from that of the nano-post NP. For example, even when the nano-post NP is formed of TiO₂, the nano-post connection layer 150 may be formed of a different material, for example, SiN, SiC, etc. This feature differs from the continuous formation of the nano-posts NP and the nano-post connection layer 150 by using the same material as described in relation to FIG. 6A.

Because the upper surface of the dielectric layer DL is planarized by using the CMP process, the interface characteristics between the nano-posts NP and the nano-post connection layer 150 may also be different from those in FIG. 6A. Adhesion force or optical characteristics at the interface may change due to the use of different materials, which may require particular consideration in the manufacturing process.

The dielectric layer DL structure between the nano-posts NP may be formed similar to that in FIG. 6A, but the interfacial characteristics with respect to the nano-post connection layer 150 may vary due to a material difference.

The forming of the nano-post connection layer 150 by using the separate process may increase the degree of freedom of material selection, and may have the advantage of independently optimizing the characteristics of the nano-post connection layer 150. In addition, the structure may provide flexibility of selectively determining a material of the nano-post connection layer 150 according to particular optical characteristics or process requirements.

FIG. 6E is a cross-sectional view illustrating a meta microlens area of the image sensor 100 according to another embodiment. FIG. 6E is, similar to FIG. 6A, an enlarged view of area B in FIG. 5, but illustrates a structure in which the thickness of the nano-post connection layer 150 is optimized.

In FIG. 6E, the nano-post NP may have a right-angled column structure extending in the vertical direction (Z direction) in the same manner as illustrated in FIG. 6A. The nano-post connection layer 150 may be continuously formed by using the same material in the same process as the nano-posts NP, and then the thickness of the nano-post connection layer 150 may be adjusted by using a CMP process.

The nano-posts NP and the nano-post connection layer 150 may be continuously formed in the same deposition process, and thus may secure good interfacial characteristics. Thereafter, the thickness of the nano-post connection layer 150 may be reduced to a desired level by using a CMP process.

The thickness of the nano-post connection layer 150 may be precisely controlled to optimize optical characteristics of the image sensor. For example, when the thickness of the nano-post connection layer 150 is excessively large, the light transmittance thereof may decrease, and when the thickness thereof is excessively small, the structural stability thereof may decrease. Accordingly, to maximize the performance of an image sensor, the thickness of the nano-post connection layer 150 may be optimized considering both the light transmittance and the structural stability.

Adjusting the thickness of the nano-post connection layer 150 by using the CMP process may improve surface flatness. The result may enable uniform deposition of an upper anti-reflection layer 160 formed by using a subsequent process, and accordingly, may further improve optical performance.

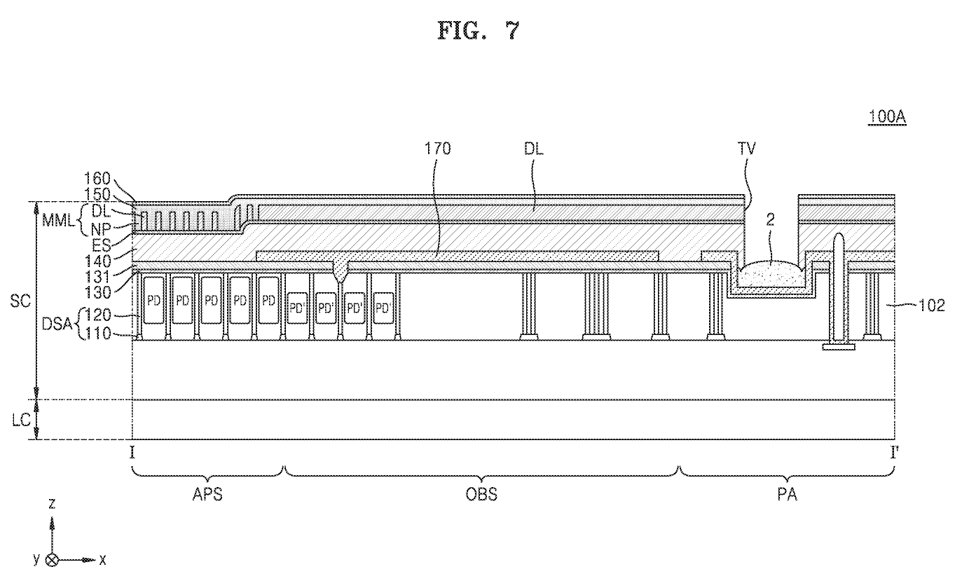

In this structure, because the nano-post NP and the nano-post connection layer 150 include the same material, stress due to a difference in the coefficient of thermal expansion may not be generated, and both the optical characteristics and structural stability may be secured by optimizing the thickness by using a CMP process. FIG. 7 illustrates a cross-sectional view of an image sensor 100A according to another embodiment.

Referring to FIG. 7, the image sensor 100A may share most of the basic components of the image sensor 100 illustrated in FIG. 4, but differs insofar as image sensor 100A lacks the scattering layer BS.

In the image sensor 100A, a trench from the backside surface 102B of the substrate 102 toward the frontside surface 102F may not be formed, and accordingly, there may be no scattering layer BS. As a result, the backside surface 102B of the substrate 102 may be in direct contact with the backside insulating layer 130. Because the substrate structure of the upper area of the photodiode PD is continuously maintained, structural stability of the substrate may be improved.

In a structure without the scattering layer BS, incident infrared rays may directly reach the photodiode PD without scattering. This structure may maintain the straightness of the incident light, and may provide an advantage in particular application fields. For example, this structure may be advantageous when high spatial resolution is required or when precise detection according to the incident angle is required.

The remaining components of the image sensor 100A, that is, the backside insulating layer 130, the lower anti-reflection layer 131, the light blocking layer 170, the planarization layer 140, the etching stopper ES, the meta microlens MML, the nano-post connection layer 150, and the upper anti-reflection layer 160 may have substantially the same configuration and characteristics as those of the image sensor 100 of FIG. 4.

Because the manufacturing process may be relatively simplified and the trench etching and filling process for forming the scattering layer is unnecessary, this structure may have the advantage of reducing the manufacturing cost.

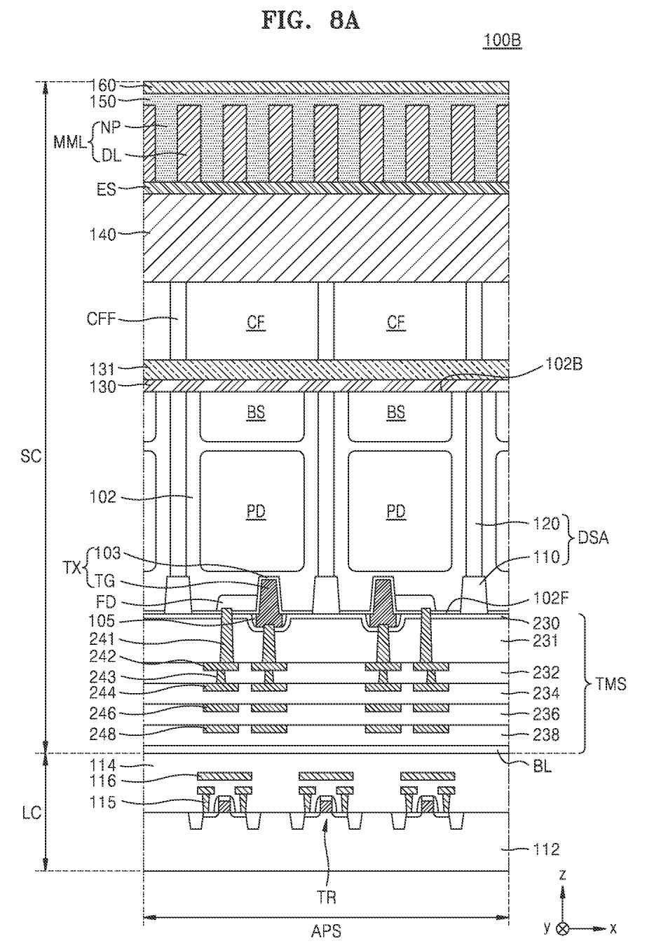

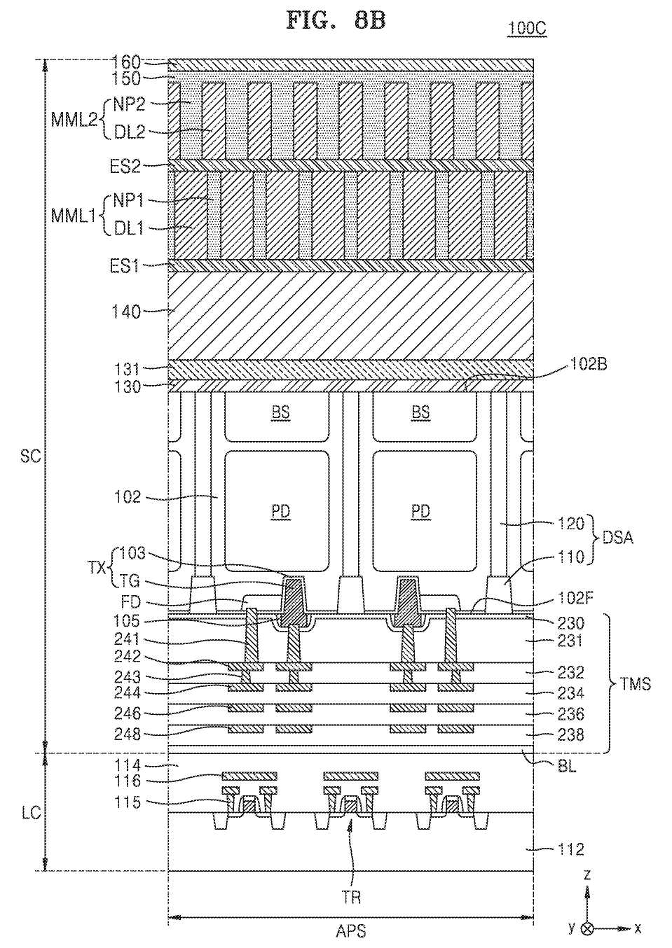

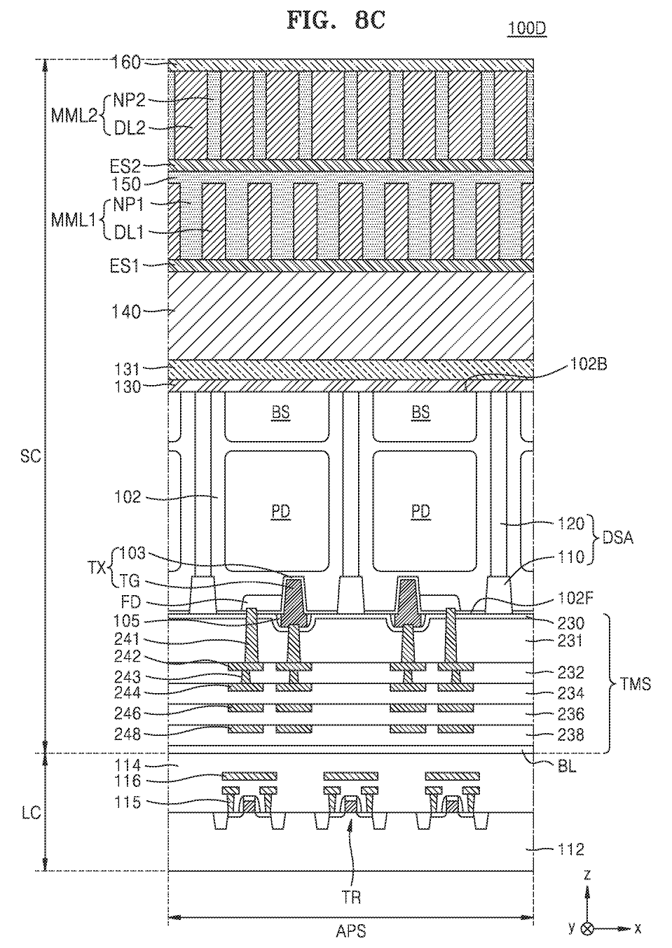

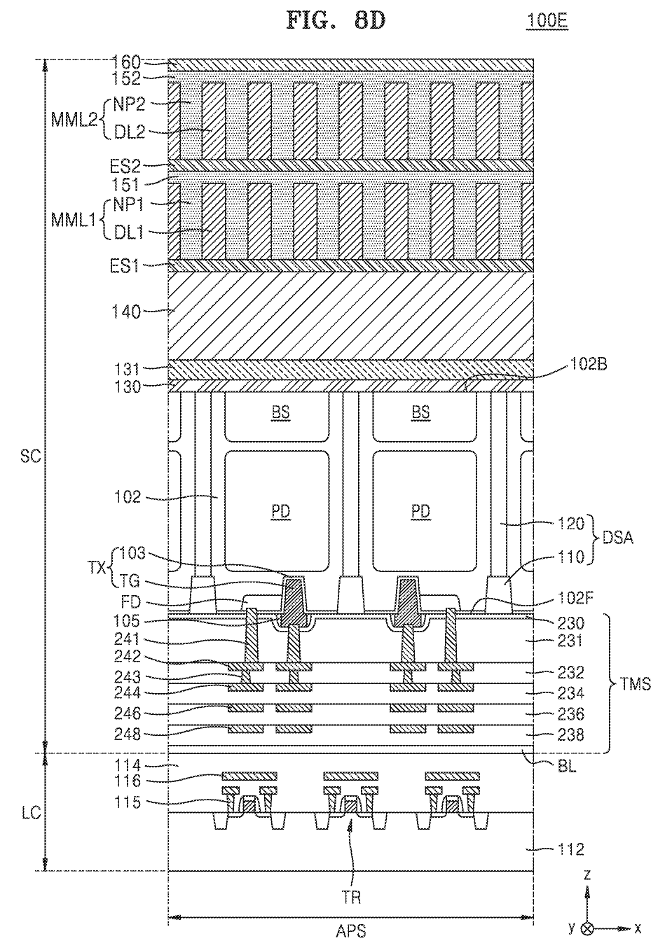

FIGS. 8A through 8D are schematic cross-sectional views of image sensors, according to one or more embodiments.

Referring to FIG. 8A, an image sensor 100B may be different from the image sensor 100 which detects infrared rays in FIG. 4, insofar as the image sensor 100B includes a color filter CF.

The image sensor 100B may further include the color filter CF arranged between the lower anti-reflection layer 131 and the planarization layer 140. The color filter CF may separate incident visible light into particular wavelength bands of red color (R), green color (G), and blue color (B). Each color filter may selectively transmit only light of a wavelength band corresponding thereto and block light of other wavelength bands. A red color filter may transmit light in a wavelength band of about 600 to about 700 nm, a green color filter may transmit light in a wavelength band of about 500 to about 600 nm, and a blue color filter may transmit light in a wavelength band of about 400 to about 500 nm.

A color filter fence CFF may be formed between the color filters CF. The color filter fence CFF may prevent optical interference between adjacent color filters and may improve color purity. The color filter fence CFF may include an opaque material that blocks light, and may clearly distinguish the boundary between the color filters CF. In this manner, it may be possible to prevent color mixing of light passing through each color filter CF and improve color reproducibility.

The meta microlens MML of the image sensor 100B may perform a unique function of separating the incident light by wavelength and condensing the separated incident light onto a color filter CF corresponding to the wavelength. This feature differentiates the meta microlens MML from conventional microlenses, and the nano-post NP structure of the meta microlens MML may enable wavelength-selective condensing. The size, distance, and arrangement of the nano-posts NP may be designed to induce light of a particular wavelength in a desired direction. By using this structure, the red color light, green color light, and blue color light may be efficiently condensed by using color filters CF respectively corresponding thereto.

The scattering layer BS may also be optimized for visible light detection. Unlike the infrared ray image sensor 100 of FIG. 4, the scattering layer BS of the image sensor 100B may be designed to exhibit effective scattering characteristics in a visible light band. The transparent resin constituting the scattering layer BS may include a material having a high transmittance in the visible light range, and the scattering material may also be selected from materials exhibiting good scattering characteristics in the visible light band.

The planarization layer 140 may perform a complex role compared to the image sensor 100 of FIG. 4. By effectively planarizing surface steps that may occur due to the forming of the color filter CF and the color filter fence CFF, it may be possible to provide a basis for uniform formation of the meta microlens MML. Because the flatness of the planarization layer 140 directly affects the wavelength-selective condensing performance of the meta microlens MML, strict process control may be required.

The entire optical structure of the image sensor 100B may be optimized for visible light detection. All optical layers from the lower anti-reflection layer 131 to the upper anti-reflection layer 160 may be configured to exhibit optimal performance in the visible light band. By forming the refractive index and thickness of each layer at values that maximize the transmittance of the visible light and minimize reflection, good optical characteristics may be realized.

By using a combination of these structural characteristics, in the image sensor 100B, the wavelength-selective condensing function of the meta microlens MML, the color separation function of the color filter CF, and the color purity improvement function of the color filter fence CFF may be organically performed, and accordingly, good color image sensing performance may be implemented.

In the image sensor 100B, because there is little light loss due to a color filter CF, for example, an organic color filter CF, a sufficient amount of light may be provided to the pixel even when the size of the pixel decreases. Thus, it may be possible to manufacture an image sensor including hundreds of millions or more of pixels having ultra-high resolution, ultra-small sizes, and high-sensitivity. Such image sensors of ultra-high resolution, ultra-small sizes, and high-sensitivity may be employed in various high performance optical devices or high performance electronic devices. The electronic device may include smartphones, mobile phones, personal digital assistants (PDAs), laptops, personal computers (PCs), various portable devices, home appliances, security cameras, medical cameras, automobiles, Internet of Things (IoT) devices, and other mobile or non-mobile computing devices, but the disclosure is not limited thereto.

In addition to the image sensor 100B, the electronic device may further include a processor that controls an image sensor (e.g., image processor 70), for example, an application processor (AP), and by driving an operating system or application program by using the processor, may control multiple hardware or software components, and may perform various data processing and calculations. The processor may further include a graphics processing unit (GPU) and/or an image signal processor. When the processor includes an image signal processor, an image (or picture) secured by an image sensor may be stored and/or outputted by using the processor.

Referring to FIG. 8B, an image sensor 100C may include two stacked meta microlenses. In the embodiment, the image sensor 100C may include a first meta microlens MML1 and a second meta microlens MML2. The second meta microlens MML2 may be arranged on the first meta microlens MML1. In other words, incident light incident on the image sensor 100C may first pass through the second meta microlens MML2, and then pass through the first meta microlens MML1.

The nano-post connection layer 150 may be arranged on the second meta microlens MML2, and a second etching stopper ES2 may be arranged between the first meta microlens MML1 and the second meta microlens MML2. The second etching stopper ES2 may have substantially the same characteristics as a first etching stopper ES1.

The thicknesses of the first meta microlens MML1 and the second meta microlens MML2 may be substantially the same. The second meta microlens MML2 may include second nano-posts NP2 having high refractive index that changes the phase of the incident light, and second dielectric layers DL2 that are respectively arranged between the second nano-posts NP2 and have a lower refractive index than the second nano-posts NP2. The second nano-posts NP2 and the second dielectric layers DL2 may include substantially the same material as first nano-posts NP1 and first dielectric layers DL1, respectively.

In an embodiment, the horizontal positions of the second nano-posts NP2 may be different from the horizontal positions of a plurality of first nano-posts NP1. In other words, the second nano-posts NP2 are offset from the first nano-posts NP1 in a horizontal direction (e.g., X direction) so that they do not vertically overlap. Rather, below a lower portion of the second nano-post NP2, the first dielectric layer DL1 may be arranged.

Like the first meta microlens MML1, the second meta microlens MML2 may perform not only simple condensing but color separation. In each of the first meta microlens MML1 and the second meta microlens MML2 included in the image sensor 100C, a combination of a case in which only condensing is possible, and a case, in which a phase of light of first wavelength is changed to condense the light of the first wavelength onto first pixel of each of the first meta microlens MML1 and the second meta microlens MML2, and a phase of light of second wavelength is changed to condense the light of the second wavelength on second pixel of each of the first meta microlens MML1 and the second meta microlens MML2, may be formed.

Like the first meta microlens MML1, the second meta microlens MML2 may perform not only simple condensing but color separation. In the image sensor 100C, functions of the first meta microlens MML1 and the second meta microlens MML2 may be implemented in various combinations.

In a first embodiment, both the first meta microlens MML1 and the second meta microlens MML2 may perform only condensing on incident light. In a second embodiment, both the first meta microlens MML1 and the second meta microlens MML2 may change a phase of light per wavelength of the incident light, and condense the phase-changed light onto each pixel corresponding to the wavelength of the incident light.

In another embodiment, the first meta microlens MML1 may perform only condensing for all incident light, and the second meta microlens MML2 may change the phase of light per wavelength of the incident light and condense the phase-changed light onto each pixel corresponding to the wavelength of the incident light. By contrast, in another embodiment, the first meta microlens MML1 may perform phase change per wavelength and condensing with respect to the incident light, and the second meta microlens MML2 may perform only condensing.

By using these various implementation methods, the image sensor 100C may perform efficient control and treatment of the incident light, and according to characteristics of each embodiment, may implement optimized optical performance for different applications.

Referring to FIG. 8C, an image sensor 100D may have a different stacked structure from the image sensor 100C of FIG. 8B. The image sensor 100D may have a structure in which the nano-post connection layer 150 is arranged on the first meta microlens MML1, and the second etching stopper ES2 and the second meta microlens MML2 are sequentially stacked on the nano-post connection layer 150. This feature differs from the embodiment of FIG. 8B insofar as the second etching stopper is arranged directly between the first meta microlens MML1 and the second meta microlens MML2, and the nano-post connection layer 150 is arranged on the second meta microlens MML2.

Due to the structural difference, in the image sensor 100D, a direct optical connection between the nano-posts NP of the first meta microlens MML1 and the nano-post connection layer 150 may be feasible, which may contribute optimization of the light transmittance characteristics. In addition, because the second etching stopper ES2 is arranged on the nano-post connection layer 150, when the second meta microlens MML2 is formed in the subsequent process, a lower structure may be effectively protected.

The upper anti-reflection layer 160 may be arranged at the uppermost portion of the image sensor 100D, and may improve the optical efficiency of the entire structure.

Referring to FIG. 8D, an image sensor 100E may include the first meta microlens MML1 and the second meta microlens MML2 sequentially stacked above the substrate 102, and a nano-post connection layer corresponding to each meta microlens.

In the image sensor 100E, the first etching stopper may be arranged on the planarization layer 140, and the first meta microlens MML1 may be arranged on the first etching stopper ES1. A first nano-post connection layer 151 may be arranged on the first meta microlens MML1, and the second etching stopper ES2 may be arranged on the first nano-post connection layer 151. The second meta microlens MML2 may be arranged on the second etching stopper ES2, and a second nano-post connection layer 152 may be arranged on the second meta microlens MML2. The upper anti-reflection layer 160 may be arranged on the second nano-post connection layer 152.

The first meta microlens MML1 may include the first nano-posts NP1 changing phase of the incident light and having a high refractive index, and the first dielectric layers DL1 arranged between the first nano-posts NP1 and having a lower refractive index than the first nano-posts NP1. The first nano-post connection layer 151 may be in contact with the first nano-posts NP1 of the first meta microlens MML1, and adjust optical characteristics of the first meta microlens MML1.

The second meta microlens MML2 may include the second nano-posts NP2 changing phase of the incident light and having a high refractive index, and the second dielectric layers DL2 arranged between the second nano-posts NP2 and having a lower refractive index than the second nano-posts NP2. The second nano-post connection layer 152 may be in contact with the second nano-posts NP2 of the second meta microlens MML2, and adjust optical characteristics of the second meta microlens MML2.

The first nano-post connection layer 151 may be formed by using the same process as the first meta microlens MML1 or by using a separate process. Similarly, the second nano-post connection layer 152 may be formed by using the same process as the second meta microlens MML2 or by using a separate process.

The first nano-post connection layer 151 and the second nano-post connection layer 152 may include the same material, and each of them may include any one of TiO₂, SiN, and SiC. In addition, the first nano-post connection layer 151 and the second nano-post connection layer 152 may also include different materials from each other.

This structure may independently control optical characteristics of each meta microlens, and accordingly, improve light condensing efficiency and color separation performance of an image sensor. In addition, the interfacial characteristics between each meta microlens and the nano-post connection layer corresponding to each meta microlens may be optimized, thus minimize optical loss.

FIGS. 8B through 8D illustrate the image sensors 100B through 100D, each having a structure in which the first meta microlens MML1 and the second meta microlens MML2 are stacked, but the disclosure is not limited thereto, and the disclosure may include three or more meta microlenses.

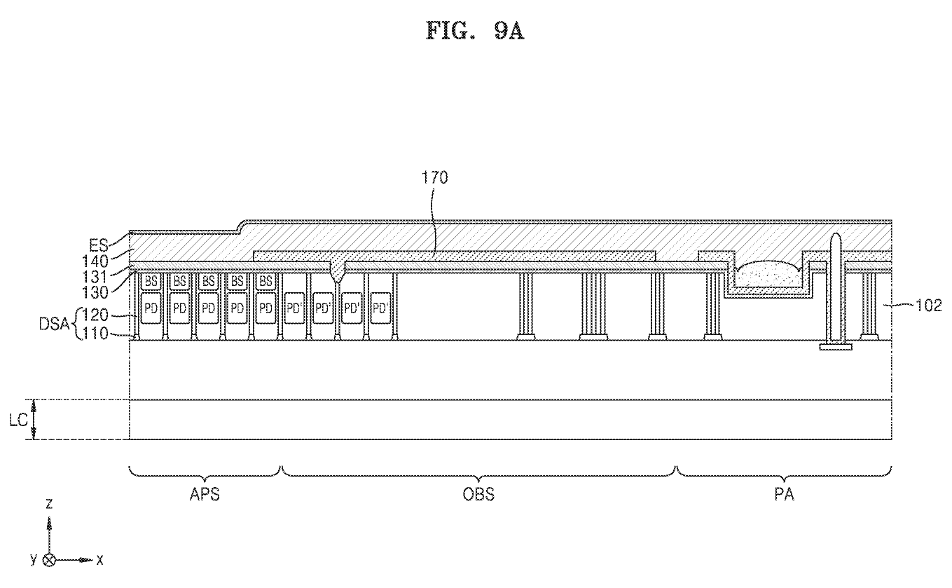

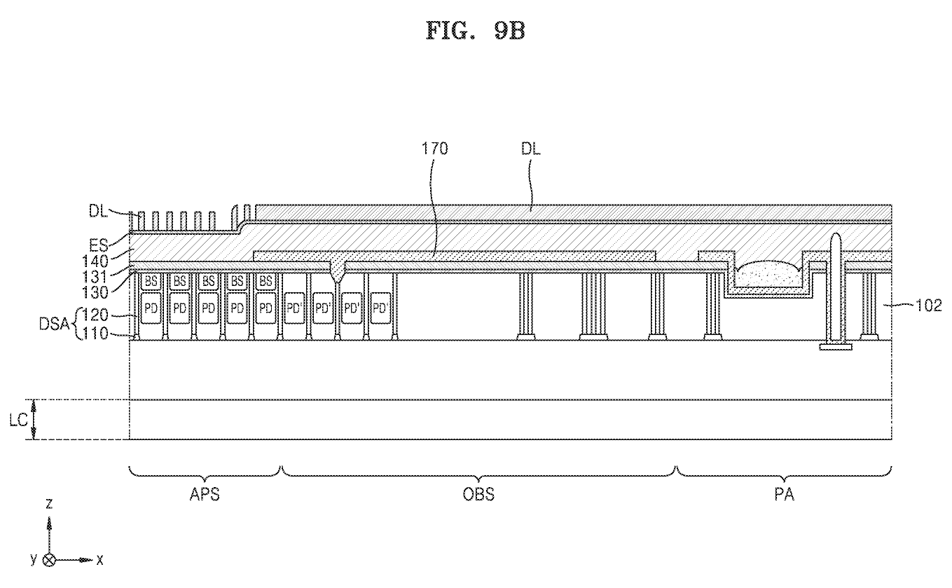

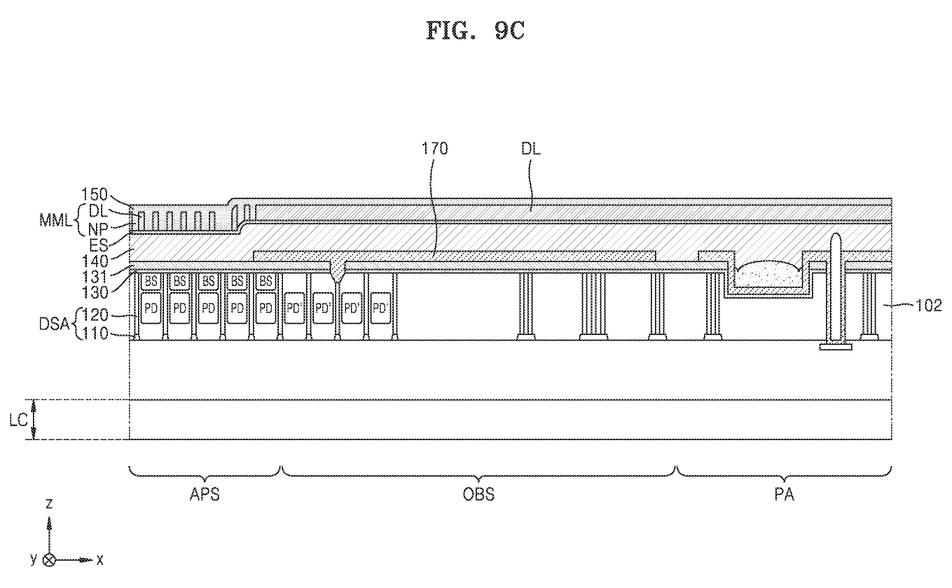

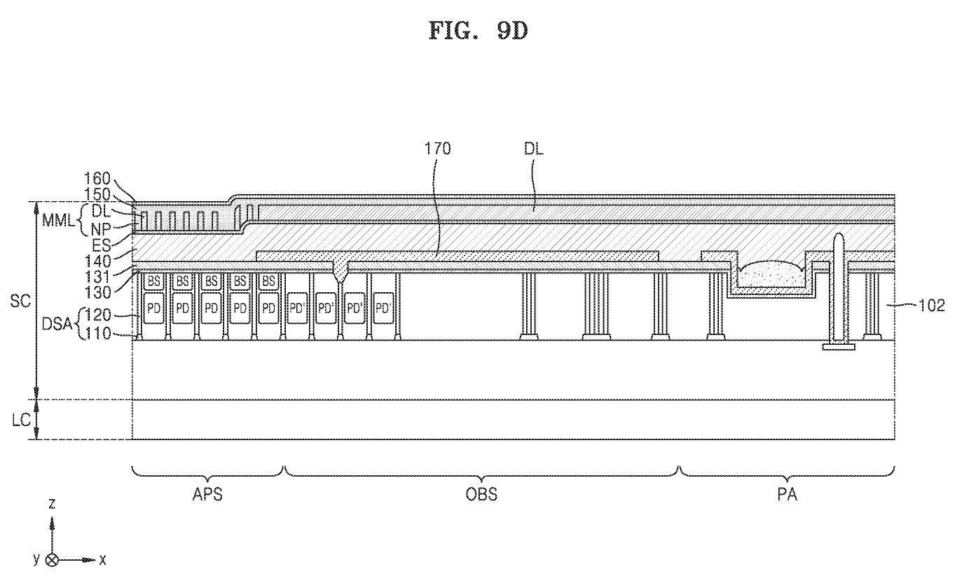

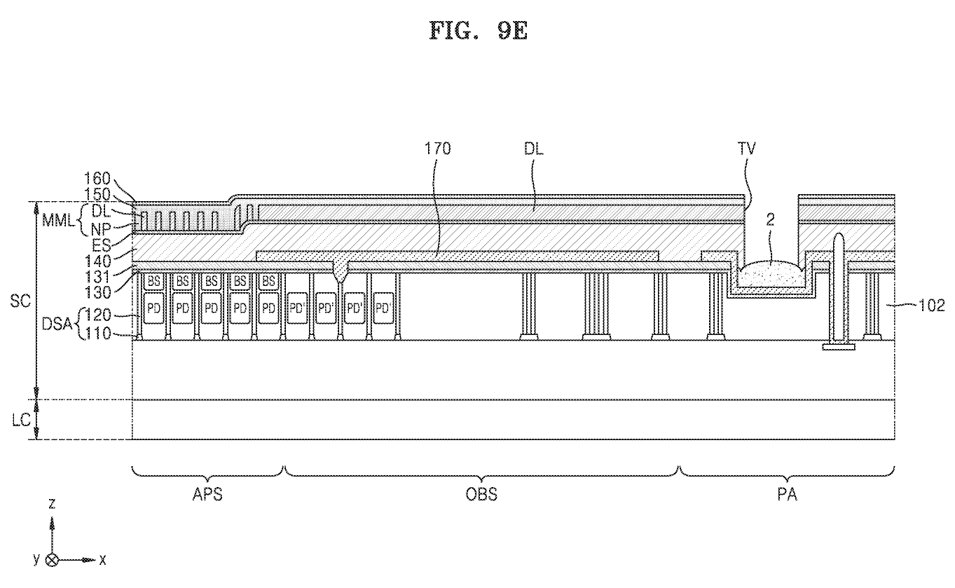

FIGS. 9A through 9E are cross-sectional views illustrating a method of manufacturing an image sensor according to a process sequence, according to one or more embodiments. FIGS. 9A through 9E illustrate cross-sectional components according to a process order of forming the meta microlens MML, the nano-post connection layer 150, and the upper anti-reflection layer 160 on the etching stopper ES. An example method of manufacturing the image sensor 100 illustrated in FIGS. 4 and 5 is described below with reference to FIGS. 9A through 9E. In FIGS. 9A through 9E, the same reference numerals as in FIGS. 1 through 4 may denote the same members, and thus detailed explanations thereof are omitted below.

Referring to FIG. 9A, the planarization layer 140 covering the lower anti-reflection layer 131 and the light blocking layer 170 may be formed. The planarization layer 140 may be formed on the front surface of the substrate 102 including the active pixel sensor area APS, the optical black sensor area OBS, and pad area PA.

The planarization layer 140 may be formed by using a material having high transmittance in the infrared band. For example, the planarization layer 140 may be formed by using a material including polysiloxane resin or silicone resin. The planarization layer 140 may be formed by using a spin coating process, and then be cured by using a heat treatment process.

The thickness of the planarization layer 140 may be determined considering a focal length of the meta microlens MML. Considering the refractive index of the planarization layer 140 at the reference wavelength of the infrared band, the thickness of the planarization layer 140 may be formed within a range of about 1/2 to about 1.5 times the focal length of the reference wavelength light.

Next, an etching stopper ES may be formed on the planarization layer 140. The etching stopper ES may be formed by using an ALD process, and using a material including at least one of aluminum oxide (AlO), hafnium oxide (HfO), and silicon nitride (SiN). These materials may exhibit good transmittance characteristics even in the infrared band.

Because the etching stopper ES protects the planarization layer 140 from being damaged during the etching process of the nano-posts NP to be formed in the subsequent process, the thickness of the etching stopper ES may be formed to be about 3 nm to about 50 nm, preferably about 5 nm to about 15 nm.

In another embodiment, when a visible light image sensor is manufactured, the material and thickness of the planarization layer 140 may be optimized to suit the visible light band. In this case, the planarization layer 140 may be formed by using a material having a high transmittance in the visible light area, such as TEOS, SiO₂, and siloxane-based spin-on-glass. For example, when the reference wavelength (λ0) is about 540 nm, which corresponds to green light, and the refractive index (n) of the planarization layer 140 at the corresponding wavelength is about 1.46, the focal length of the green light may become about 1.64 μm, and thus the thickness of the planarization layer 140 may be formed within the range of about 0.82 μm to about 2.46 μm.

To pattern the etching stopper ES, photoresist may be first doped thereon, and then a pattern corresponding to lower areas of the nano-posts NP to be formed in the subsequent process may be formed by using exposure and development processes. Next, by selectively patterning the etching stopper ES by performing an etching process, an increase in reflectance due to the etching stopper ES may be reduced.

Referring to FIG. 9B, the dielectric layer DL for forming the nano-post NP of the meta microlens MML on the etching stopper ES may be formed. The dielectric layer DL may include a material having high transmittance in the infrared band, and may be formed by using an ALD process.

As a material of the dielectric layer DL, air, SiO₂, TEOS, or a combination thereof may be used. These materials may provide good optical characteristics and high refractive indices in the infrared wavelength region. By using the ALD process, the dielectric layer DL having a uniform thickness and good step coatability may be formed.

The thickness of the dielectric layer DL may be determined considering the height of the nano-posts NP for a phase control of the meta microlens MML. For example, when a center wavelength is infrared rays of about 940 nm, the thickness of the dielectric layer DL may be formed, for example, within a range of about 400 nm to about 6000 nm. The thickness may be a height sufficient to implement 2π phase modulation in infrared wavelengths, and may be a thickness range for securing also the structural stability of the nano-post NP.

After nitride film coating (NFC) on the dielectric layer DL is formed, a low temperature oxide (LTO) layer may be formed. The NFC may be used as a hard mask in a subsequent etching process, and may be formed to a thickness of about 200 ̊ to about 8000 ̊. The NFC may be formed by using a plasma-enhanced CVD (PECVD) process, and the process temperature for the PECVD process may be in the range of about 300 °C to about 400 °C.

The LTO layer may be formed to have a thickness of about 500 ̊ to about 2000 ̊ on the NFC. The LTO layer may be formed by using a low pressure CVD (LPCVD) process, and the process temperature for the LPCVD process may be in the range of about 300 °C to about 400 °C. The LTO layer may improve adhesion to the photoresist to be formed in a subsequent process.

Next, a photoresist (PR) may be doped on the LTO layer, and an exposure process may be performed by using a mask corresponding to the nano-post NP pattern. The PR may be doped by using a spin coating method, and the thickness of the PR may be adjusted to be in a range of about 0.5 μm to about 2 μm. The thickness of the PR may be optimized by considering a selection ratio of the subsequent etching process and an aspect ratio of the pattern.

The exposure process may be performed by using a photolithography process using KrF excimer laser (wavelength about 248 nm) or ArF excimer laser (wavelength about 193 nm) as a light source. Exposure energy and focal depth may be optimized to accurately implement the critical dimension of the nano-post NP pattern during the exposure process.

A nano-post NP pattern may be formed by removing the exposed PR by using the development process. The size and spacing of the nano-post NP pattern may be determined according to design specifications of the meta microlens MML. In general, the diameter of the nano-post NP may be in a range of about 1/3 to about 2/3 of the wavelength, and the spacing (pitch) between the nano-posts NP may be designed to be less than the wavelength to prevent the diffraction effect.

For example, when the center wavelength is about 940 nm, the diameter of the nano-post NP may be designed in a range of about 300 nm to about 600 nm, and the pitch between the nano-posts NP may be designed to be equal to or less than about 800 nm. These dimensions may be optimized by considering both the phase control performance of a meta microlens and the stability of the manufacturing process.

The formed PR pattern may be used as a mask in a subsequent etching process to form a nano-post NP structure in the dielectric layer DL. In this case, a desired nano-post NP profile may be obtained by appropriately controlling the selection ratio and anisotropy of the etching process.

Referring to FIG. 9C, the nano-post NP and the nano-post connection layer 150 may be formed on the patterned dielectric layer. According to an embodiment, the nano-post NP and the nano-post connection layer 150 may be continuously formed by using the same material in the same process.

The nano-post NP and the nano-post connection layer 150 may be formed by using a material including TiO₂ having high transmittance in the infrared band. After the nano-post NP is formed by using an ALD process, the nano-post connection layer 150 may be formed by continuously performing the same process. The ALD process may be performed in a temperature range of about 150 °C to about 300 °C, which is set in consideration of the thermal stability of the lower structure.

By continuously forming the nano-post NP and the nano-post connection layer 150 in the same process as described above, a separate CMP process may not be required, and the interfacial characteristics between the nano-post NP and the nano-post connection layer 150 may be improved. In addition, this continuous process may have the advantage of reducing manufacturing costs by using process simplification.

According to another embodiment, the nano-post NP and the nano-post connection layer 150 may be formed by using different processes. After the nano-post NP is formed, the nano-post connection layer 150 may be formed by using a separate process. In this case, the nano-post connection layer 150 may be formed by using a different material from the nano-post NP. For example, even when the nano-post NP is formed of TiO₂, the nano-post connection layer 150 may be formed of a different material, for example, SiN, SiC, etc.

The nano-post connection layer 150 may be continuously formed over an area including all of the active pixel sensor area APS, the optical black sensor area OBS, and the pad area PA of the image sensor 100. The thickness of the nano-post connection layer 150 may be formed in a range of about 100 nm to about 500 nm, which may be determined to optimize the structural stability and optical performance.

The nano-post connection layer 150 may be formed in consideration of, for example, interfacial characteristics with respect to the upper anti-reflection layer 160 formed thereon. Surface roughness (RMS) may be controlled to be about 1 nm or less, which may directly affect an adhesion force and optical characteristics with the upper anti-reflection layer 160.

The forming of the nano-post connection layer 150 by using the separate process may increase the degree of freedom of material selection, and may have the advantage of independently optimizing the characteristics of the nano-post connection layer 150. In addition, the separate process may provide flexibility of selectively determining a material of the nano-post connection layer 150 according to particular optical characteristics or process requirements.

When necessary, a heat treatment process may be performed after the nano-post connection layer 150 is formed. The heat treatment process may be performed in a temperature range of about 200 °C to about 400 °C for about 10 minutes to about 60 minutes, which may be necessary for densification and stress relief of a connection layer.

Referring to FIG. 9D, the upper anti-reflection layer 160 may be formed on the nano-post connection layer 150. In an embodiment, the upper anti-reflection layer 160 may be formed as a single layer, and in other embodiments, may be formed as a plurality of layers.

When the upper anti-reflection layer 160 is formed as a single layer, the refractive index of the upper anti-reflection layer 160 may be formed to be less than the refractive index of the meta microlens MML and greater than the refractive index of air. For example, when the refractive index of the meta microlens MML is about 1.69, the refractive index of the upper anti-reflection layer 160 may be formed within a range of less than about 1.69 and greater than about 1. The thickness of the upper anti-reflection layer 160 of a single layer may be selected within a range of about 100 Å to about 2000 Å, and may be formed by using an ALD process or a CVD process. In the case of a single layer structure, the process may be simplified to reduce manufacturing costs, but the anti-reflection performance may be somewhat limited compared to a multi-layer structure.

When formed as a plurality of layers, the upper anti-reflection layer 160 may be formed in a structure in which the third sub reflection layer, the second sub reflection layer, and the first sub reflection layer are sequentially stacked from the meta microlens MML. In this case, a plurality of upper anti-reflection layers may be stacked to overlap each other in the vertical direction (Z direction), and the refractive index of each layer may be formed to increase in a direction toward the meta microlens MML.

The refractive index of the second sub reflection layer may be formed to be less than the refractive index of the third sub reflection layer, and greater than the refractive index of the first sub reflection layer. The refractive index of each of the plurality of upper anti-reflection layers may be formed to linearly increase by about 0.2 nm for a thickness of every about 100 nm in the vertical direction (Z direction). For example, the refractive index and the thickness of the first sub reflection layer may be about 1.22 and about 1000 Å, the refractive index and the thickness of the second sub reflection layer may be about 1.35 and about 1000 Å, and the refractive index and the thickness of the first sub reflection layer may be about 1.46 and about 1000 Å, respectively.

In this multi-layer structure, when the incident light is reflected by the light incident surface of the meta microlens MML, a path from an area with a larger refractive index to an area with a less refractive index may be formed, and total reflection or refraction may occur. In this manner, the intensity of reflected light may be effectively reduced, and improved anti-reflection performance compared to the single-layer structure may be provided. In addition, the thickness and refractive index of each layer may be independently optimized, and thus good anti-reflection characteristics in various wavelength bands may be implemented.

Referring to FIG. 9E, a process of exposing a pad 2 in the pad area PA may be performed. This process may include a process of exposing the pad 2 by removing the upper anti-reflection layer 160, the nano-post connection layer 150, the meta microlens MML, the etching stopper ES, and the planarization layer 140 in the pad area PA.

Firstly, the PR may be coped and patterned to expose the upper anti-reflection layer 160 in an area where the pad 2 is arranged. Next, the upper anti-reflection layer 160 may be selectively removed by using an etching process. When the upper anti-reflection layer 160 is formed of a plurality of layers, an optimized etching condition in consideration of material characteristics of each layer may be applied.

Next, the nano-post connection layer 150 and a nano-post structure of the meta microlens MML may be etched. In this process, an etching process that has a high selection ratio with respect to a material of the nano-post NP (for example, TiO₂, SiN, and SiC) may be used. An etching process may be performed by using an anisotropic dry etching, and a sidewall profile and etching uniformity may be precisely controlled.

Next, a process of removing the etching stopper ES may be performed. Because the etching stopper ES includes AlO, HfO, or SiN, a selective etching process may be applied to these materials. The etching selectivity and time may be optimized so that the planarization layer 140 under the etching stopper ES is not damaged during the etching process.

Finally, by removing the planarization layer 140, the pad 2 may be completely exposed. Because the planarization layer 140 includes an oxide-based material, the planarization layer 140 may be selectively removed by using a hydrofluoric acid (HF)-based wet etching solution or a carbon fluoride-based dry etching gas. After the etching process, a cleaning process for removing the oxide layer or residue from the surface of the pad 2 may be additionally performed.

The pad 2 may be completely exposed by using this series of etching processes, and the exposed pad 2 may be used, in a subsequent process, for wire bonding or bump forming for electrical connection to an external circuit. It may be important to precisely control the process conditions so that the structure around the pad 2 is not damaged throughout the etching process.

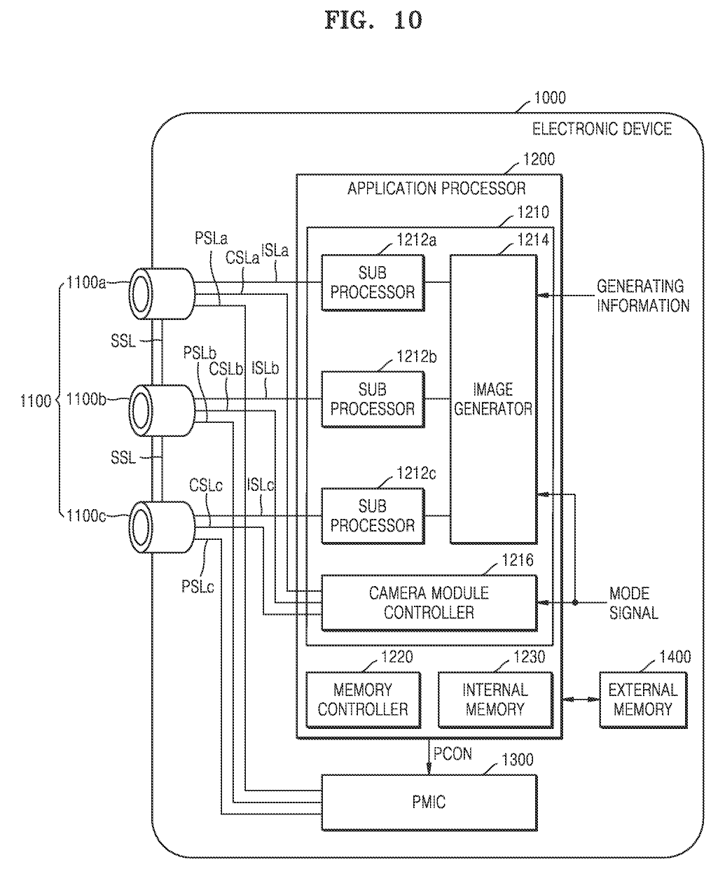

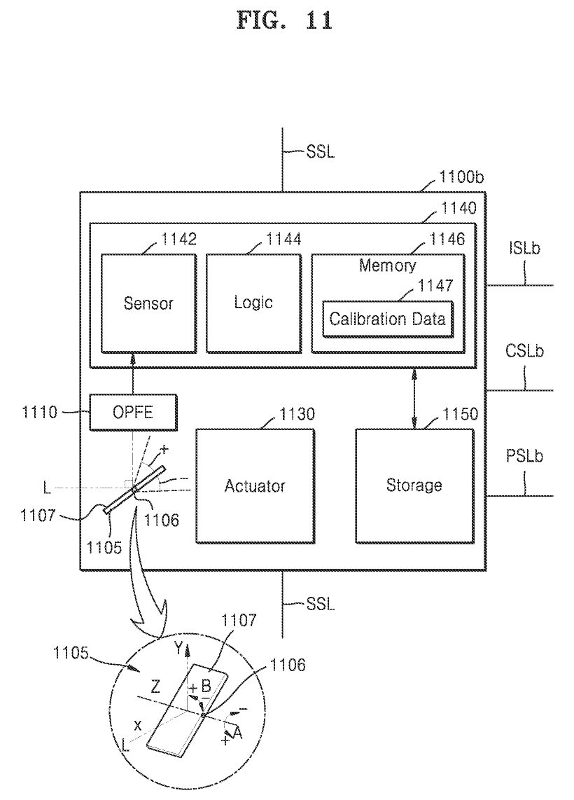

FIG. 10 is a block diagram of an electronic system 1000 according to an embodiment, and FIG. 11 is a detailed block diagram of a camera module 1100b included in the electronic system 1000 of FIG. 10.

Referring to FIG. 10, the electronic system 1000 may include a camera module group 1100, an application processor 1200, a power management integrated circuit (PMIC) 1300, and an external memory 1400.

The camera module group 1100 may include a plurality of camera modules 1100a, 1100b, and 1100c. The drawing illustrates an embodiment in which three camera modules 1100a, 1100b, and 1100c are arranged, but the disclosure is not limited thereto. In one or more embodiments, the camera module group 1100 may be modified and embodied to include only two camera modules. In addition, in one or more embodiments, the camera module group 1100 may also be modified and embodied to include n camera modules (where n is a natural number equal to or greater than 4).

Hereinafter, detailed configurations of the camera module 1100b are described with reference to FIG. 11, but the descriptions below may be identically applied to other camera modules 1100a and 1100c according to one or more embodiments.

Referring to FIG. 11, the camera module 1100b may include a prism 1105, an optical path folding element (hereinafter, referred to as OPFE) 1110, an actuator 1130, and an image sensing device 1140, and a storage 1150.

The prism 1105 may include a reflection surface 1107 including a light reflecting material, and change a path of light L incident from the outside.

In one or more embodiments, the prism 1105 may change the path of the light L incident in a first direction (X direction in FIG. 11) to a second direction (Y direction in FIG. 11) perpendicular to the first direction (X direction). In addition, the prism 1105 may rotate in direction A with a center axis 1106 of the reflection surface 1107 of the light reflecting material as a center, or rotate the center axis 1106 in direction B to change the path of the light L incident in the first direction (X direction) to the second direction (Y direction) perpendicular to the first direction (X direction). In this case, the OPFE 1110 may also be moved to a third direction (Z direction in FIG. 11) perpendicular to the first direction (X direction) and the second direction (Y direction).

In one or more embodiments, as illustrated in FIG. 11, the maximum rotation angle in the direction A of the prism 1105 may be equal to or less than about 15 degrees in a plus (+) direction A, and greater than about 15 degrees in a minus (-) direction A, but the disclosure is not limited thereto.

In one or more embodiments, the prism 1105 may move within about 20 degrees, or between about 10 degrees and about 20 degrees, or between about 15 degrees and about 20 degrees in a plus (+) or minus (-) direction B, and in this case, the movement angles may be the same degrees, or almost similar degrees to each other within a range of about 1 degree in the plus (+) or the minus (-) direction B.

In one or more embodiments, the prism 1105 may move the reflection surface 1107 of the light reflecting material to a third direction (for example, the Z direction) in parallel with an extended direction of the center axis 1106.

The OPFE 1110 may include, for example, an optical lens including m groups (where m is a natural number). The m optical lenses may be moved in the second direction (Y direction) to change an optical zoom ratio of the camera module 1100b. For example, when a basic optical zoom ratio of the camera module 1100b is defined as Z, and m optical lenses included in the OPFE 1110 are moved, the optical zoom ratio of the camera module 1100b may be changed to an optical zoom ratio of 3Z, 5Z, or more.

The actuator 1130 may move the OPFE 1110 or the optical lens (hereinafter, referred to as an optical lens) to a certain position. For example, the actuator 1130 may adjust a position of the optical lens so that an image sensor 1142 is at a focal length of the optical lens for an accurate sensing.

The image sensing device 1140 may include the image sensor 1142, a control logic 1144, and a memory 1146. The sensor 1142 may sense an image of a sensing target by using the light L provided via the optical lens. The control logic 1144 may control the entire operation of the camera module 1100b. For example, the control logic 1144 may control an operation of the camera module 1100b according to a control signal provided via a control signal line CSLb.

The memory 1146 may store information, such as calibration data 1147, required for the operation of the camera module 1100b. The calibration data 1147 may include information required by the camera module 1100b for generating image data by using the light L provided from the outside. The calibration data 1147 may include, for example, information about the degree of rotation, information about a focal length, information about an optical axis, or the like described above. When the camera module 1100b is implemented in a multi-state camera type in which a focal length varies according to a position of the optical lens, the calibration data 1147 may include information about a focal length value per position (or per state) of the optical lens and information about auto-focusing.

The storage 1150 may store the image data sensed by the image sensor 1142. The storage 1150 may be arranged outside the image sensing device 1140, and may be implemented in a form in which the storage 1150 is stacked with a sensor chip constituting the image sensing device 1140. In one or more embodiments, the storage 1150 may be implemented as electrically erasable programmable read-only memory (ROM) (EEPROM), but the embodiment is not limited thereto.

The image sensor 1142 may include the image sensors 100, 100A, and 100B described above with reference to FIGS. 1 through 8, or an image sensor variously modified and changed from these image sensors within the scope of the technical idea of the disclosure. Accordingly, the disclosure may simplify the manufacturing process by forming the meta microlens MML and the nano-post connection layer 150 in the same process, and may improve light condensing efficiency by using a combination of the nano-post structural optimization and the upper anti-reflection layer 160.

Referring to FIGS. 10 and 11 together, in one or more embodiments, each of a plurality of camera modules 1100a, 1100b, and 1100c may include the actuator 1130. Accordingly, each of the plurality of camera modules 1100a, 1100b, and 1100c may include identical or different calibration data 1147 to or from each other, according to an operation of the actuator 1130 included in each thereof.

In one or more embodiments, one camera module (for example, 1100b) among the plurality of camera modules 1100a, 1100b, and 1100c may include a folded lens-type camera module including the prism 1105 and the OPFE 1110 described above, and the remaining camera modules (for example, 1100a and 1100c) may include a vertical-type camera module that does not include the prism 1105 and the OPFE 1110, but the disclosure is not limited thereto.

In one or more embodiments, one camera module (for example, 1100c) among the plurality of camera modules 1100a, 1100b, and 1100c may include a vertical-type depth camera, in which depth information is extracted by using, for example, infrared ray (IR). In this case, the application processor 1200 may generate a three-dimensional (3D) depth image by merging image data provided by the depth camera with image data provided by another camera module (for example, 1100a or 1100b).

In one or more embodiments, at least two camera modules (for example, 1100a and 1100b) among the plurality of camera modules 1100a, 1100b, and 1100c may have different field of views from each other. In this case, for example, the optical lenses of at least two camera modules (for example, 1100a and 1100b) among the plurality of camera modules 1100a, 1100b, and 1100c may be different from each other, but the embodiment is not limited thereto.

In addition, in one or more embodiments, the field of view of each of the plurality of camera modules 1100a, 1100b, and 1100c may be different. In this case, the optical lenses included in each of the plurality of camera modules 1100a, 1100b, and 1100c may also be different from each other, but the embodiment is not limited thereto.

In one or more embodiments, each of the plurality of camera modules 1100a, 1100b, and 1100c may be arranged physically apart from each other. In other words, a sensing area of one image sensor 1142 may not be divided and used by the plurality of camera modules 1100a, 1100b, and 1100c, but the image sensor 1142 may be arranged independently inside each of the plurality of camera modules 1100a, 1100b, and 1100c.

Referring again to FIG. 10, the application processor 1200 may include an image processing device 1210 (e.g., image processor 70), a memory controller 1220, and an internal memory 1230. The application processor 1200 may be implemented isolated from the plurality of camera modules 1100a, 1100b, and 1100c. For example, the application processor 1200 and the plurality of camera modules 1100a, 1100b, and 1100c may be implemented isolated from each other in isolated semiconductor chips.

The image processing device 1210 may include a plurality of sub processors 1212a, 1212b, and 1212c, an image generator 1214, and a camera module controller 1216. The image processing device 1210 may include the plurality of sub processors 1212a, 1212b, and 1212c having the number thereof corresponding to the number of the plurality of camera modules 1100a, 1100b, and 1100c.

The image data generated by each of the plurality of camera modules 1100a, 1100b, and 1100c may be provided to the plurality of sub processors 1212a, 1212b, and 1212c via image signal lines ISLa, ISLb, and ISLc which are isolated from each other, respectively. For example, the image data generated by the camera module 1100a may be provided to the sub processor 1212a via an image signal line ISLa, the image data generated by the camera module 1100b may be provided to the sub processor 1212b via an image signal line ISLb, and the image data generated by the camera module 1100c may be provided to the sub processor 1212c via the image signal line ISLc. Transmission of the image data may be performed by using, for example, a camera serial interface (CSI) based on a mobile industry processor interface (MIPI), but the embodiment is not limited thereto.

On the other hand, in one or more embodiments, one sub image processor may also be arranged to correspond to a plurality of camera modules. For example, the sub processor 1212a and the sub processor 1212c may not be implemented as isolated from each other as illustrated, but may be implemented as integrated into one sub image processor, and the image data provided by the camera module 1100a and the camera module 1100c may, after being selected by a selection element (for example, a multiplexer) or the like, be provided to the integrated sub image processor.

The image data provided to each of the plurality of sub processors 1212a, 1212b, and 1212c may be provided to the image generator 1214. The image generator 1214 may generate an output image by using the image data provided by each of the plurality of sub processors 1212a, 1212b, and 1212c according to image generation information or a mode signal.

The image generator 1214 may generate an output image by merging at least some of the image data generated by the plurality of camera modules 1100a, 1100b, and 1100c having different field of views from each other, according to the image generation information or the mode signal. In addition, the image generator 1214 may generate an output image by selecting at least one of the image data generated by the plurality of camera modules 1100a, 1100b, and 1100c having different field of views from each other, according to the image generation information or the mode signal.

In one or more embodiments, the image generation information may include a zoom signal (or zoom factor). In addition, in one or more embodiments, the mode signal may include, for example, a signal based on a mode selected by a user.

When the image generation information includes the zoom signal (zoom factor), and each of the plurality of camera modules 1100a, 1100b, and 1100c have different fields of view from each other, the image generator 1214 may perform different operations from each other according to types of the zoom signals. For example, when the zoom signal includes a first signal, after merging the image data output by the camera module 1100a with the image data output by the camera module 1100c, output image may be generated by using the merged image signal with the image data output by the camera module 1100b which has not been used in the merging. When the zoom signal includes a second signal different from the first signal, the image generator 1214 may not perform the merging operation on the image data, but may generate the output image by selecting any one piece of the image data output by each of the plurality of camera modules 1100a, 1100b, and 1100c. However, the disclosure is not limited thereto, and a method of processing the image data may be modified and performed as necessary.

In one or more embodiments, by receiving a plurality of image data having different exposure times from each other from at least one of the plurality of sub processors 1212a, 1212b, and 1212c, and performing a high dynamic range (HDR) processing on the plurality of image data, the image generator 1214 may generate the merged image data with an increased dynamic range.

The camera module controller 1216 may provide a control signal to each of the plurality of camera modules 1100a, 1100b, and 1100c. The control signal generated by the camera module controller 1216 may be provided to the plurality of camera modules 1100a, 1100b, and 1100c via control signal lines CSLa, CSLb, and CSLc, which are isolated from each other, respectively.

Any one of the plurality of camera modules 1100a, 1100b, and 1100c, for example, the camera module 1100b may be designated as a master camera module according to image generation information or a mode signal including a zoom signal, and the remaining camera modules, for example, 1100a and 1100c, may be designated as slave cameras. These pieces of information may be included in the control signal, and may be provided to the plurality of camera modules 1100a, 1100b, and 1100c via the control signal lines CSL1, CSLb, and CSLc, which are isolated from each other, respectively.

According to a zoom factor or an operation mode signal, camera modules operating as the master camera module and the slave camera module may be changed. For example, when the field of view of the camera module 1100a is greater than the field of view of the camera module 1100b, and indicates a zoom ratio having a low zoom factor, the camera module 1100b may operate as the master camera module, and the camera module 1100a may operate as the slave camera module. On the other hand, when the field of view indicates a zoom ratio having a high zoom ratio, the camera module 1100a may operate as the master camera module, and the camera module 1100b may operate as the slave camera module.

In one or more embodiments, the control signal provided by the camera module controller 1216 to each of the plurality of camera modules 1100a, 1100b, and 1100c may include a sync enable signal. For example, when the camera module 1100b includes the master camera, and the camera modules 1100a and 1100c include the slave cameras, the camera module controller 1216 may transmit the sync enable signal to the camera module 1100b. The camera module 1100b having received the sync enable signal may generate a sync signal based on the received sync enable signal, and provide the generated sync signal to the camera modules 1100a and 1100c via a sync enable signal line SSL. The camera module 1100b and the camera modules 1100a and 1100c may be synchronized to the sync signal, and transmit the image data to the application processor 1200.

In one or more embodiments, the control signal provided by the camera module controller 1216 to the plurality of camera modules 1100a, 1100b, and 1100c may include mode information according to the mode signal. Based on the mode information, the plurality of camera modules 1100a, 1100b, and 1100c may operate in a first operation mode and second operation mode with respect to a sensing speed.

The plurality of camera modules 1100a, 1100b, and 1100c may, in the first operation mode, generate the image signal at a first speed (for example, generate the image signal at a first frame rate), encode the generated image signal at a second speed greater than the first speed (for example, encode the generated image signal at a second frame rate greater than the first frame rate), and transmit the encoded image signal to the application processor 1200. In this case, the second speed may be equal to or less than about 30 times the first speed.

The application processor 1200 may store the received image signal, that is, the encoded image signal, in the internal memory 1230 or the external memory 1400 outside the application processor 1200, thereafter, may read and decode the encoded image signal from the internal memory 1230 or the external memory 1400, and may display the image data, that is generated based on the decoded image signal. For example, a sub processor corresponding to the plurality of sub processors 1212a, 1212b, and 1212c of the image processing device 1210 may perform decoding, and may perform an image processing on the decoded image signal.

The plurality of camera modules 1100a, 1100b, and 1100c may, in the second operation mode, generate the image signal at a third speed less than the first speed (for example, generate the image signal at a third frame rate less than the first frame rate), and transmit the image signal to the application processor 1200. The image signal provided to the application processor 1200 may include an un-encoded signal. The application processor 1200 may perform the image processing on the received image signal, or store the received image signal in the internal memory 1230 or the external memory 1400.

The PMIC 1300 may provide power, for example, a power voltage to each of the plurality of camera modules 1100a, 1100b, and 1100c. For example, the PMIC 1300 may, under the control of the application processor 1200, provide a first power to the camera module 1100a via a power signal line PSLa, provide a second power to the camera module 1100b via a power signal line PSLb, and provide a third power to the camera module 1100c via a power signal line PSLc.

The PMIC 1300 may, in response to a power control signal PCON from the application processor 1200, generate power corresponding to each of the plurality of camera modules 1100a, 1100b, and 1100c, and in addition, may adjust a level of the generated power. The power control signal PCON may include a power adjustment signal per operation mode of the plurality of camera modules 1100a, 1100b, and 1100c. For example, the operation mode may include a low power mode, and in this case, the power control signal PCON may include information about a camera module operating at the low power mode and information about a set power level. The levels of power provided to each of the plurality of camera modules 1100a, 1100b, and 1100c may be the same as or different from each other. In addition, the level of power may be dynamically changed.

At least one of the components, elements, modules, units, or the like (collectively "components" in this paragraph) represented by a block or an equivalent indication (collectively “block”) in the above embodiments including the drawings such as FIGS. 2, 10, and 11, for example, the timing controller, the row driver, the column driver, the readout circuit, logic, processors, controllers, or the like, may carry out the above-described function or functions. These blocks may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

While the disclosure has been particularly shown and described with reference to one or more embodiments thereof, it will be understood that various change in form and details may be made therein without departing from the spirit and scope of the following claims.

What is claimed is:

1. An image sensor comprising:
a substrate comprising a pixel configured to sense light;
at least one meta microlens on the substrate;
a reflection prevention layer on the at least one meta microlens; and
a nano-post connection layer between the at least one meta microlens and the reflection prevention layer,
wherein the at least one meta microlens comprises:
a dielectric layer; and
a nano-post penetrating the dielectric layer and extending upward from the substrate, and
wherein the nano-post connection layer is in contact with an upper portion of the nano-post.

2. The image sensor of claim 1, wherein the nano-post connection layer and the nano-post comprise a same material.

3. The image sensor of claim 1, wherein the nano-post connection layer extends continuously on the at least one meta microlens.

4. The image sensor of claim 1, wherein the nano-post comprises TiO₂.

5. The image sensor of claim 1, wherein the nano-post connection layer is in direct contact with the reflection prevention layer.

6. The image sensor of claim 1, wherein a refractive index of the reflection prevention layer is less than a refractive index of the at least one meta microlens and is greater than a refractive index of air.

7. The image sensor of claim 1, wherein the reflection prevention layer comprises a plurality of sub reflection prevention layers each having a different refractive index.

8. An image sensor comprising:
a substrate comprising a photodiode;
a meta microlens on the substrate, the meta microlens comprising a plurality of nano-posts;
a nano-post connection layer on the meta microlens; and
a reflection prevention layer on the nano-post connection layer,
wherein the nano-post connection layer and the plurality of nano-posts are formed by a same process, and
wherein the nano-post connection layer extends along an upper surface of the plurality of nano-posts.

9. The image sensor of claim 8, wherein the substrate comprises an active pixel sensor area and an optical black sensor area, and wherein the nano-post connection layer extends across the active pixel sensor area and the optical black sensor area.

10. The image sensor of claim 8, wherein a width of each of the plurality of nano-posts increases as a distance from the substrate increases.

11. The image sensor of claim 8, wherein a width of each of the plurality of nano-posts decreases as a distance from the substrate increases.

12. The image sensor of claim 8,
wherein the reflection prevention layer comprises:
a first sub reflection layer having a first refractive index;
a second sub reflection layer having a second refractive index greater than the first refractive index; and
a third sub reflection layer having a third refractive index greater than the second refractive index, and
wherein the third sub reflection layer is in contact with the nano-post connection layer.

13. The image sensor of claim 8, wherein the nano-post connection layer and the plurality of nano-posts each comprise TiO_{2.}

14. The image sensor of claim 8, wherein the meta microlens further comprises a dielectric layer between the plurality of nano-posts.

15. An image sensor comprising:
a photodiode inside a substrate;
a planarization layer on the substrate;
at least one meta microlens on the planarization layer;
a nano-post connection layer on the meta microlens; and
a reflection prevention layer on the nano-post connection layer,
wherein the at least one meta microlens comprises:
a dielectric layer; and
a plurality of nano-posts configured to penetrate the dielectric layer and extend upward from the substrate,
wherein the nano-post connection layer extends along an upper surface of the plurality of nano-posts and comprises a same material as the plurality of nano-posts, and
wherein the reflection prevention layer comprises a plurality of sub reflection prevention layers each having a different refractive index.

16. The image sensor of claim 15, wherein the plurality of nano-posts each have a reverse tapered shape comprising a width that increases as a distance from the substrate increases.

17. The image sensor of claim 15, wherein the plurality of nano-posts each have a tapered shape comprising a width that decreases as a distance from the substrate increases.

18. The image sensor of claim 15, further comprising an etching stopper between the planarization layer and the at least one meta microlens.

19. The image sensor of claim 15, wherein the refractive index of each of the plurality of sub reflection prevention layers increases sequentially from an upper surface of the image sensor moving toward the at least one meta microlens.

20. The image sensor of claim 15, further comprising:
a plurality of color filters between the substrate and the planarization layer; and
a color filter fence between adjacent color filters among the plurality of color filters.
